(19) United States
(12) Patent Application Publication
(10) Pub. No.: US 2025/0366293 A1
(43) Pub. Date: Nov. 27, 2025

(54) DISPLAY DEVICE

(71) Applicant: Samsung Display Co., LTD., Yongin-si (KR)

(72) Inventors: Sun PARK, Yongin-si (KR); Bo Bae LEE, Yongin-si (KR); Yu Jin LEE, Yongin-si (KR); Jung An LEE, Yongin-si (KR)

(21) Appl. No.: 18/976,127

(22) Filed: Dec. 10, 2024

(30) Foreign Application Priority Data
May 27, 2024 (KR) 10-2024-0068469

(51) Int. Cl. H10H 29/49

(52) U.S. Cl. CPC H10H 29/49

(57) ABSTRACT

A display device includes a substrate, a pixel electrode and a common electrode on the substrate, an organic layer on the pixel electrode and the common electrode, a light emitting element on the organic layer and including a semiconductor stack and a first contact electrode and a second contact electrode on one surface of the semiconductor stack and a first connection electrode connecting the first contact electrode and the pixel electrode and a second connection electrode connecting the second contact electrode and the common electrode, wherein the first connection electrode is between the first contact electrode and the organic layer and extends onto the pixel electrode on which the organic layer is not located, wherein the second connection electrode is disposed between the second contact electrode and the organic layer and extends onto the common electrode on which the organic layer is not located, and wherein the first connection electrode and the second connection electrode expose at least a portion of the organic layer on a surface where the light emitting element and the organic layer overlap.

### CROSS-REFERENCE TO RELATED APPLICATION

The present application claims priority to and the benefit of Korean Patent Application No. 10-2024-0068469, filed on May 27, 2024, in the Korean Intellectual Property Office, the entire disclosure of which is incorporated by reference herein.

### BACKGROUND

### 1. Field

The present disclosure relates to a display device.

### 2. Description of the Related Art

As the information society develops, the demand for display devices for displaying images is increasing in various forms. The display device may be a flat panel display such as a liquid crystal display, a field emission display, a light emitting display, and the like.

The light emitting display device may include an organic light emitting display device including an organic light emitting diode (OLED) element as a light emitting element, and a micro light emitting display device including a micro light emitting diode element (hereinafter referred to as a micro light emitting diode element) as a light emitting element. Because the micro light emitting diode element is made of inorganic materials, it has the advantage of having less deterioration issues and may have a longer lifespan compared to an organic light emitting diode (OLED) element.

### SUMMARY

Aspects and features of embodiments of the present disclosure are to provide a display device and a manufacturing method thereof that may stably support a light emitting element while preventing side leakage current of the light emitting element.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the present disclosure, a display device includes a substrate, a pixel electrode and a common electrode on the substrate, an organic layer on the pixel electrode and the common electrode, a light emitting element on the organic layer and including a semiconductor stack and a first contact electrode and a second contact electrode on one surface of the semiconductor stack and a first connection electrode connecting the first contact electrode and the pixel electrode and a second connection electrode connecting the second contact electrode and the common electrode, wherein the first connection electrode is between the first contact electrode and the organic layer and extends onto the pixel electrode on which the organic layer is not located, wherein the second connection electrode is disposed between the second contact electrode and the organic layer and extends onto the common electrode on which the organic layer is not located, and wherein the first connection electrode and the second connection electrode expose at least a portion of the organic layer on a surface where the light emitting element and the organic layer overlap.

The organic layer contacts the light emitting element in an area exposed by the first connection electrode and the second connection electrode.

Each of a width of the first connection electrode and a width of the second connection electrode is narrower than a width of the light emitting element in a plan view.

The first connection electrode and the second connection electrode have one or more through-holes or one or more concave portions that are concave in a plane on a surface overlapping the organic layer.

The organic layer contacts the light emitting element through the through-holes or the concave portions.

The through-hole has one of a circular shape, an oval shape, or a polygonal shape in a plane.

The first connection electrode and the second connection electrode are spaced from each other in a plane, and a first organic layer is filled between the first connection electrode and the second connection electrode.

The light emitting element further comprises, a conductive layer between the organic layer and the semiconductor stack and a protective film on one side and other sides of the conductive layer and sides of the semiconductor stack, wherein the first contact electrode is on the protective film and connected to the conductive layer exposed and not covered by the protective film, and the second contact electrode is on the protective film and is located in a hole that penetrates through the conductive layer and a portion of the semiconductor stack.

Each of the first contact electrode and the second contact electrode is spaced from a top surface of the light emitting element.

The semiconductor stack includes a first semiconductor layer, an active layer, and a second semiconductor layer arranged along a thickness direction of the light emitting element, wherein the first contact electrode and the second contact electrode are on an entire side surface of the conductive layer and the first semiconductor layer, on an entire side surface of the active layer, and on a portion of a side surface of the second semiconductor layer.

The semiconductor stack includes a first semiconductor layer, an active layer, and a second semiconductor layer arranged along a thickness direction of the light emitting element, wherein the first contact electrode and the second contact electrode are on an entire side surface of the conductive layer, the first semiconductor layer, and the active layer, and expose an entire side surface of the second semiconductor layer.

The first contact electrode and the second contact electrode expose an entire side surface of the semiconductor stack.

The protective film is spaced from a top surface of the light emitting element by a first distance, and wherein each of the first contact electrode and the second contact electrode is spaced from the top surface of the light emitting element by a second distance, wherein the second distance is greater than the first distance.

The semiconductor stack further comprises, a first semiconductor layer on the organic layer and including a semiconductor material layer doped with a first conductivity type dopant, an active layer on the first semiconductor layer and a second semiconductor layer on the active layer and including a semiconductor material layer doped with a second conductivity type dopant, wherein a hole penetrating a portion of the semiconductor stack exposes the second semiconductor layer, and wherein the second contact electrode is in contact with the exposed second semiconductor layer.

A display device comprises a substrate, a pixel electrode on the substrate, an organic layer on the pixel electrode, a light emitting element on the organic layer and including a semiconductor stack and a contact electrode on one surface of the semiconductor stack and a connection electrode between the contact electrode and the organic layer and extending onto the pixel electrode on which the organic layer is not located, and connecting the contact electrode and the pixel electrode, wherein the connection electrode exposes at least a portion of the organic layer on a surface where the light emitting element and the organic layer overlap.

The organic layer is in contact with the light emitting element in an area exposed by the connection electrode.

The a width of the connection electrode is narrower than a width of the light emitting element in a plane view.

The connection electrode has one or more through-holes or one or more concave portions that are concave in a plane on a surface overlapping the organic layer.

The organic layer is in contact with the light emitting element through the through-holes or the concave portions.

The through-hole has one of a circular shape, an oval shape, or a polygonal shape in a plane.

According to one or more embodiments, an electronic device including a display device, the display device includes: a substrate; a pixel electrode and a common electrode on the substrate; an organic layer on the pixel electrode and the common electrode; a light emitting element on the organic layer and comprising a semiconductor stack and a first contact electrode and a second contact electrode on one surface of the semiconductor stack; and a first connection electrode connecting the first contact electrode and the pixel electrode and a second connection electrode connecting the second contact electrode and the common electrode, wherein the first connection electrode is between the first contact electrode and the organic layer and extends onto the pixel electrode on which the organic layer is not located, wherein the second connection electrode is between the second contact electrode and the organic layer and extends onto the common electrode on which the organic layer is not located, wherein the first connection electrode and the second connection electrode expose at least a portion of the organic layer on a surface where the light emitting element and the organic layer overlap, and wherein the first connection electrode and the second connection electrode are spaced from each other in a plane, and a first organic layer is filled between the first connection electrode and the second connection electrode.

The electronic device is a mobile phone, a smartphone, a tablet personal computer (PC), a smart watch, a watch phone, a mobile communication terminal, an electronic notebook, an electronic book, a portable multimedia player (PMP), a navigation device, an ultra-mobile PC (UMPC), a television, a notebook computer, a monitor, a billboard, or an Internet of things (IoT) device.

According to the display device and its manufacturing method according to the embodiments, the light emitting device may be stably supported while preventing side leakage current of the light emitting element.

However, the effects of the present disclosure are not limited to the aforementioned effects, and various other effects are included in the present specification.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to one or more embodiments.

FIG. 2 is a layout view of the display device according to one or more embodiments.

FIG. 3 is a block diagram of the display device according to one or more embodiments.

FIG. 4 is an equivalent circuit diagram of a subpixel according to one or more embodiments.

FIG. 5 is a layout diagram illustrating pixels of a display area according to one or more embodiments.

FIG. 6 is a cross-sectional view illustrating an example cross-section of one display panel corresponding to the lines I-I′ in FIG. 5.

FIG. 7 is a cross-sectional view illustrating one example of an area A in FIG. 6 in detail.

FIG. 8 is a cross-sectional view illustrating another example of the area A in FIG. 6 in detail.

FIG. 9 is a plan view illustrating the associated structure of a light emitting element, a connection electrode, and an organic layer in a sub-pixel according to one or more embodiments.

FIGS. 10-12 are cross-sectional views illustrating another example of the area A in FIG. 6 in detail.

FIG. 13 is a detailed cross-sectional view illustrating another example of the area A of FIG. 6.

FIG. 14 is a plan view illustrating the associated structure of the light emitting element, the connection electrode, and the organic layer in the sub-pixel corresponding to FIG. 13.

FIG. 15 is a detailed cross-sectional view illustrating another example of the area A of FIG. 6.

FIG. 16 is a plan view illustrating the associated structure of a light emitting element, a connection electrode, and an organic layer in the sub-pixel corresponding to FIG. 15.

FIG. 17 is a layout diagram illustrating pixels of a display area according to one or more embodiments.

FIG. 18 is a cross-sectional view illustrating an example of a cross-section of a display panel corresponding to the line I2-I2′ of FIG. 17.

FIG. 19 is a cross-sectional view illustrating an example of an area B in FIG. 18 in detail.

FIG. 20 is a plan view illustrating an example of a sub-pixel according to one or more embodiments.

FIG. 21 is a detailed cross-sectional view illustrating another example of the area B of FIG. 18.

FIG. 22 is a plan view illustrating associated structures of light emitting elements, connection electrodes, and organic layers in the sub-pixel corresponding to FIG. 21.

FIG. 23 is an example view of a smart watch including a display device according to one or more embodiments;

FIGS. 24 and 25 are example views of a virtual reality (VR) device including a display device according to one or more embodiments;

FIG. 26 is an example view of a VR device including a display device according to one or more embodiments;

FIG. 27 is an example view illustrating a vehicle instrument cluster and center fascia including display devices according to one or more embodiments; and

FIG. 28 is an example view of a transparent display device including a display device according to one or more embodiments.

### DETAILED DESCRIPTION

Embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts that are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

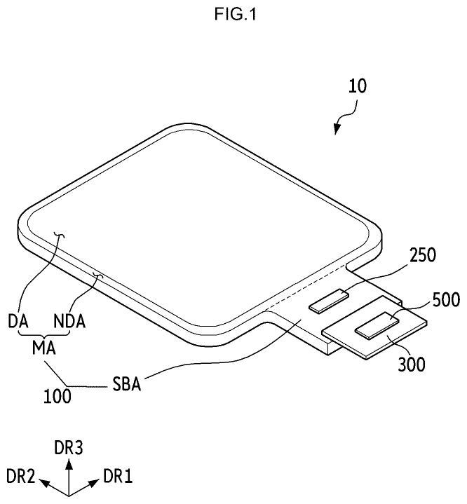

FIG. 1 is a perspective view of a display device 10 according to an embodiment.

Referring to FIG. 1, the display device 10 is a device for displaying moving images or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and/or Internet of things (IoT) devices.

The display device 10 may be a light emitting display such as an organic light emitting display using an organic light emitting diode (OLED), a quantum dot light emitting display including a quantum dot light emitting layer, an inorganic light emitting display including an inorganic semiconductor, or a micro- or nano-light emitting display using a micro- or nano-light emitting diode (LED). A case where the display device 10 is a micro- or nano-light emitting display will be mainly described below, but the present disclosure is not limited thereto. For ease of description, a micro- or nano-LED will be referred to as a light emitting element.

The display device 10 includes a display panel 100, a display driving circuit 250, a circuit board 300, and a power supply unit 500.

The display panel 100 may be shaped like a rectangular plane having short sides in a first direction DR1 and long sides in a second direction DR2 intersecting the first direction DR1. Each corner where a short side extending in the first direction DR1 meets a long side extending in the second direction DR2 may be rounded to have a suitable curvature (e.g., a predetermined curvature) or may be right-angled. The planar shape of the display panel 100 is not limited to a quadrangular shape but may also be other polygonal shapes, a circular shape, or an elliptical shape. The display panel 100 may be formed flat, but embodiments are not limited thereto. For example, the display panel 100 may include a curved portion formed at left and right ends and having a constant or varying curvature. In addition, the display panel 100 may be formed to be flexible so that it can be curved, bent, folded, and/or rolled.

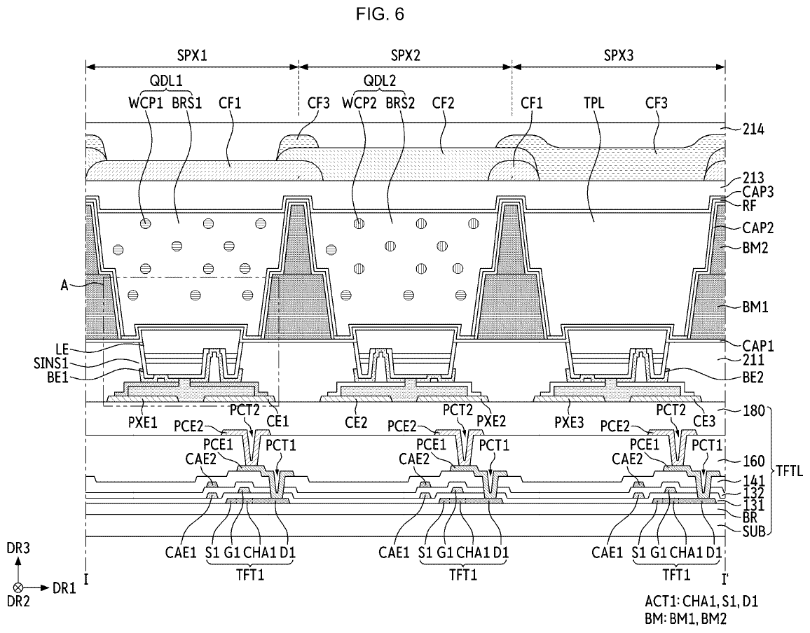

A substrate SUB (e.g., see FIG. 6) of the display panel 100 may include a main area MA and a sub-area SBA.

The main area MA may include a display area DA which displays an image and a non-display area NDA disposed around the display area DA along an edge or a periphery of the display area DA. The display area DA may include a plurality of pixels that displays an image. Each of the pixels may include a plurality of subpixels. For example, each of the pixels may include a first subpixel that emits light of a first color, a second subpixel that emits light of a second color, and a third subpixel that emits light of a third color, but the present disclosure is not limited thereto.

The sub-area SBA may protrude from a side of the main area MA in the second direction DR2. Although the sub-area SBA is unfolded in FIG. 1, it may be bent. In this case, the sub-area SBA may be placed on a lower surface of the display panel 100. When the sub-area SBA is bent, it may be overlapped by the main area MA in a third direction DR3 which is a thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit and attached onto the display panel 100 using a chip on glass (COG) method, a chip on plastic (COP) method, and/or an ultrasonic bonding method. However, the present disclosure is not limited thereto. For example, the display driving circuit 250 may also be attached onto the circuit board 300 using a chip on film (COF) method.

The circuit board 300 may be attached to an end of the sub-area SBA of the display panel 100. Accordingly, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board (FPCB), a printed circuit board (PCB), or a flexible film such as a chip on film (COF).

The power supply unit 500 may generate a plurality of panel driving voltages according to a power supply voltage from the outside. The power supply unit 500 may be formed as an integrated circuit (IC) and attached onto the circuit board 300 using a COF method.

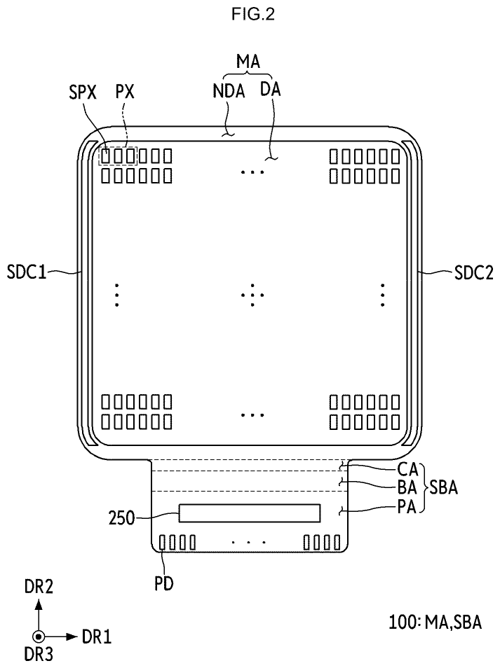

FIG. 2 is a layout view of the display device 10 according to one or more embodiments. FIG. 2 illustrates a state in which the sub-area SBA is unfolded without being bent.

Referring to FIG. 2, the display panel 100 may include the main area MA and the sub-area SBA.

The main area MA may include the display area DA that displays an image and the non-display area NDA disposed around the display area DA. The display area DA may occupy most of the main area MA. The display area DA may be disposed in a center of the main area MA.

The display area DA may include a plurality of pixels PX for displaying an image, and each of the pixels PX may include a plurality of subpixels SPX. A pixel PX may be defined as a smallest subpixel group that can express a white gray level.

The non-display area NDA may neighbor the display area DA. The non-display area NDA may be an area outside the display area DA. The non-display area NDA may be around (e.g., may surround) the display area DA. The non-display area NDA may be an edge area of the display panel 100.

A first scan driver SDC1 and a second scan driver SDC2 may be disposed in the non-display area NDA. The first scan driver SDC1 may be disposed on a side (e.g., a left side) of the display panel 100, and the second scan driver SDC2 may be disposed on the other side (e.g., a right side) of the display panel 100. However, the present disclosure is not limited thereto.

Each of the first scan driver SDC1 and the second scan driver SDC2 may be electrically connected to the display driving circuit 250 through scan fan-out lines. Each of the first scan driver SDC1 and the second scan driver SDC2 may receive a scan control signal from the display driving circuit 250, generate scan signals according to the scan control signal, and output the scan signals to scan lines.

The sub-area SBA may protrude from a side of the main area MA in the second direction DR2. A length of the sub-area SBA in the second direction DR2 may be smaller than a length of the main area MA in the second direction DR2. A length of the sub-area SBA in the first direction DR1 may be smaller than a length of the main area MA in the first direction DR1 or may be substantially equal to the length of the main area MA in the first direction DR1. The sub-area SBA may be bent and placed under the display panel 100. In this case, the sub-area SBA may be overlapped by the main area MA in the third direction DR3.

The sub-area SBA may include a connection area CA, a pad area PA, and a bending area BA.

The connection area CA is an area protruding from a side of the main area MA in the second direction DR2. A side of the connection area CA may contact the non-display area NDA of the main area MA, and the other side of the connection area CA may contact the bending area BA.

The pad area PA is an area where pads PD and the display driving circuit 250 are disposed. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. A side of the pad area PA may contact the bending area BA.

The bending area BA is a bendable area. When the bending area BA is bent, the pad area PA may be placed under the connection area CA and the main area MA. The bending area BA may be disposed between the connection area CA and the pad area PA. A side of the bending area BA may contact the connection area CA, and the other side of the bending area BA may contact the pad area PA.

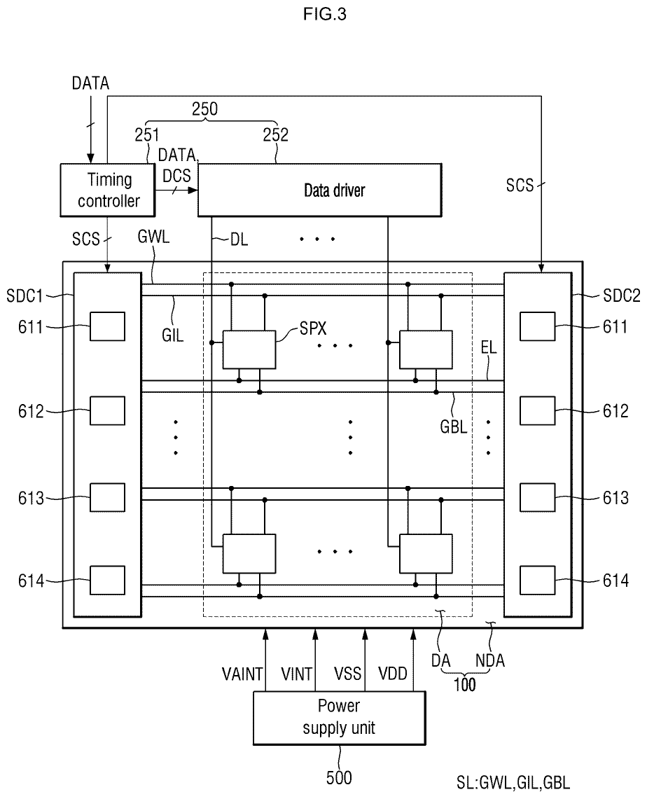

FIG. 3 is a block diagram of the display device 10 according to one or more embodiments.

Referring to FIG. 3, the display area DA includes a plurality of pixels PX, each of the pixels PX may be including a plurality of subpixels SPX, a plurality of scan lines SL, a plurality of emission control lines EL, and a plurality of data lines DL.

The pixels PX may be arranged in a matrix form along the first direction DR1 and the second direction DR2. For example, the pixels PX may be arranged along rows and columns of a matrix along the first direction DR1 and the second direction DR2. The scan lines SL and the emission control lines EL may extend in the first direction DR1 and may be arranged along the second direction DR2. The data lines DL may extend in the second direction DR2 and may be arranged along the first direction DR1. The scan lines SL include a plurality of write scan lines GWL, a plurality of initialization scan lines GIL, and a plurality of bias scan lines GBL.

Each of the subpixels SPX may be connected to one of the write scan lines GWL, one of the initialization scan lines GIL, one of the bias scan lines GBL, one of the emission control lines EL, and one of the data lines DL. In one or more embodiments, each of a plurality of subpixels SPX may also be connected to one of control scan lines. Each of the subpixels SPX may receive a data voltage of a data line DL according to a write scan signal of a write scan line GWL and may emit light from a light emitting element according to the data voltage.

The non-display area NDA includes the first scan driver SDC1, the second scan driver SDC2, and the display driving circuit 250.

Each of the first scan driver SDC1 and the second scan driver SDC2 may include a write scan signal output unit 611, a control scan signal output unit 612, an initialization scan signal output unit 613, a bias scan signal output unit 614. Each of the write scan signal output unit 611, the control scan signal output unit 612, the initialization scan signal output unit 613, the bias scan signal output unit 614, and the emission signal output unit 615 may receive a scan timing control signal SCS from a timing controller 251. The write scan signal output unit 611 may generate write scan signals according to the scan timing control signal SCS of the timing controller 251 and sequentially output the write scan signals to the write scan lines GWL. The control scan signal output unit 612 may generate control scan signals according to the scan timing control signal SCS and sequentially output the control scan signals to the control scan lines. The initialization scan signal output unit 613 may generate initialization scan signals according to the scan timing control signal SCS and sequentially output the initialization scan signals to the initialization scan lines GIL. The bias scan signal output unit 614 may generate bias scan signals according to the scan timing control signal SCS and sequentially output the bias scan signals to the bias scan lines GBL. The emission signal output unit 615 may generate emission control signals according to the scan timing control signal SCS and sequentially output the emission control signals to the emission control lines EL.

The display driving circuit 250 includes the timing controller 251 and a data driver 252.

The data driver 252 may receive digital video data DATA and a data timing control signal DCS from the timing controller 251. The data driver 252 converts the digital video data DATA into analog data voltages according to the data timing control signal DCS and outputs the analog data voltages to the data lines DL. In this case, subpixels SPX may be selected by write scan signals of the first scan driver SDC1 and the second scan driver SDC2, and the data voltages may be supplied to the selected subpixels SPX.

The timing controller 251 may receive the digital video data DATA and timing signals from the outside. The timing controller 251 may generate the scan timing control signal SCS and the data timing control signal DCS for controlling the display panel 100 according to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate a plurality of panel driving voltages according to a power supply voltage from the outside. For example, the power supply unit 500 may generate a first driving voltage VDD, a second driving voltage VSS and a third driving voltage VINT and supply them to the display panel 100.

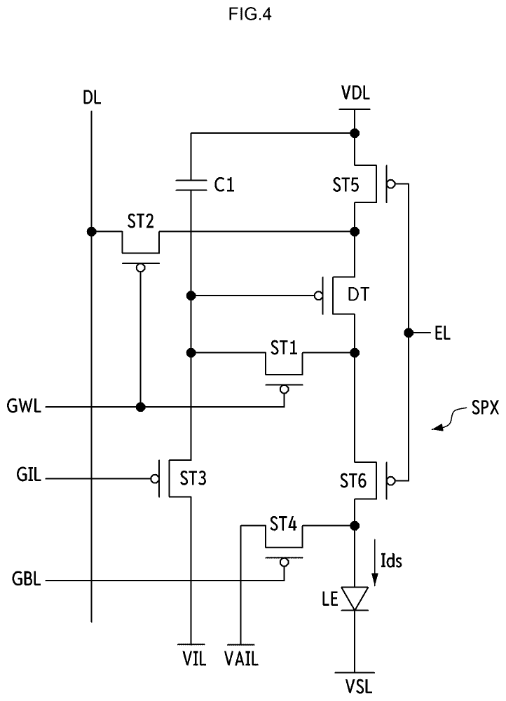

FIG. 4 is an equivalent circuit diagram of a subpixel SPX according to one or more embodiments.

Referring to FIG. 4, the subpixel SPX according to the embodiment may be connected to scan lines GWL, GIL, and GBL, an emission control line EL, and a data line DL. For example, the subpixel SPX may be connected to a write scan line GWL, an initialization scan line GIL, a bias scan line GBL, the emission line EL, and the data line DL.

The subpixel SPX according to the embodiment includes a driving transistor DT, switch elements, a capacitor C1, and a light emitting element LE. The switch elements include first through sixth transistors ST1 through ST6.

The driving transistor DT includes a gate electrode, a first electrode, and a second electrode. The driving transistor DT controls a drain-source current Ids (hereinafter, referred to as a “driving current”) flowing between the conductive layer and the second electrode according to a data voltage applied to the gate electrode.

The light emitting element LE may be a micro-LED.

The light emitting element LE emits light according to the driving current Ids. The amount of light emitted from the light emitting element LE may be proportional to the driving current Ids. An anode of the light emitting element LE may be connected to a first electrode of the fourth transistor ST4 and a second electrode of the sixth transistor ST6, and a cathode may be connected to a second power line VSL to which a second power supply voltage (e.g., the second driving voltage VSS) is applied.

The capacitor C1 is formed between the second electrode of the driving transistor DT and a first power line VDL to which a first power supply voltage (e.g., the first driving voltage VDD) is applied. The first power supply voltage may be at a higher level than the second power supply voltage. One electrode of the capacitor C1 may be connected to the second electrode of the driving transistor DT, and the other electrode may be connected to the first power line VDL.

As illustrated in FIG. 4, the first through sixth transistors ST1 through ST6 and the driving transistor DT may all be formed as p-type metal-oxide-semiconductor field effect transistors (MOSFETs). In this case, an active layer of each of the first through sixth transistors ST1 through ST6 and the driving transistor DT may be made of polysilicon.

A gate electrode of the first transistor ST1 and a gate electrode of the second transistor ST2 may be connected to the write scan line GWL, a gate electrode of the third transistor ST3 may be connected to the initialization scan line GIL, a gate electrode of the fourth transistor ST4 may be connected to the bias scan line GBL, and gate electrodes of the fifth and sixth transistors ST5 and ST6 may be connected to the light emitting control line EL. Because the first through sixth transistors ST1 through ST6 are formed as p-type MOSFETs, they may be turned on when a scan signal of a gate-low voltage and an emission control signal of a gate-low voltage are transmitted to the initialization scan line GIL, the write scan line GWL, the bias scan line GBL, and the emission line EL. One electrode of the third transistor ST3 may be connected to an initialization voltage line VIL to which the third power supply voltage VINT (see FIG. 3) is applied, and one electrode of the fourth transistor ST4 may be connected to a second initialization voltage line VAIL to which the fourth power supply voltage VAINT (see FIG. 3) is applied. The third power supply voltage VINT (see FIG. 3) and the fourth power supply voltage VAINT (see FIG. 3) may be different voltages. In addition, the third power supply voltage VINT (see FIG. 3) and the fourth power supply voltage VAINT (see FIG. 3) may be at a lower level than the first power supply voltage VDD and may be at a higher level than the second power supply voltage VSS.

Alternatively, the driving transistor DT, the second transistor ST2, the fourth transistor ST4, the fifth transistor ST5 and the sixth transistor ST6 may be formed as p-type MOSFETs, and the first transistor ST1 and the third transistor ST3 may be formed as n-type MOSFETs. The active layer of each of the driving transistor DT, the second transistor ST2, the fourth transistor ST4, the fifth transistor ST5 and the sixth transistor ST6 formed as p-type MOSFETs may be made of polysilicon, and the active layer of each of the first transistor ST1 and the third transistor ST3 formed as n-type MOSFETs may be made of an oxide semiconductor.

In this case, because the first transistor ST1 and the third transistor ST3 are formed as n-type MOSFETs, the first transistor ST1 may be turned on in response to a scan signal of a gate-high voltage, and the third transistor ST3 may be turned on in response to an initialization scan signal of a gate-high voltage. On the other hand, because the second transistor ST2, the fourth transistor ST4, the fifth transistor ST5 and the sixth transistor ST6 are formed as p-type MOSFETs, they may be turned on in response to a scan signal of a gate-low voltage and an emission control signal of a gate-low voltage.

Alternatively, the fourth transistor ST4 may be formed as an n-type MOSFET. In this case, the active layer of the fourth transistor ST4 may be made of an oxide semiconductor. When the fourth transistor ST4 is formed as an n-type MOSFET, it may be turned on in response to a scan signal of a gate-high voltage.

Alternatively, the first through sixth transistors ST1 through ST6 and the driving transistor DT may all be formed as n-type MOSFETs. In this case, the active layer of each of the first through sixth transistors ST1 through ST6 and the driving transistor DT may be made of an oxide semiconductor.

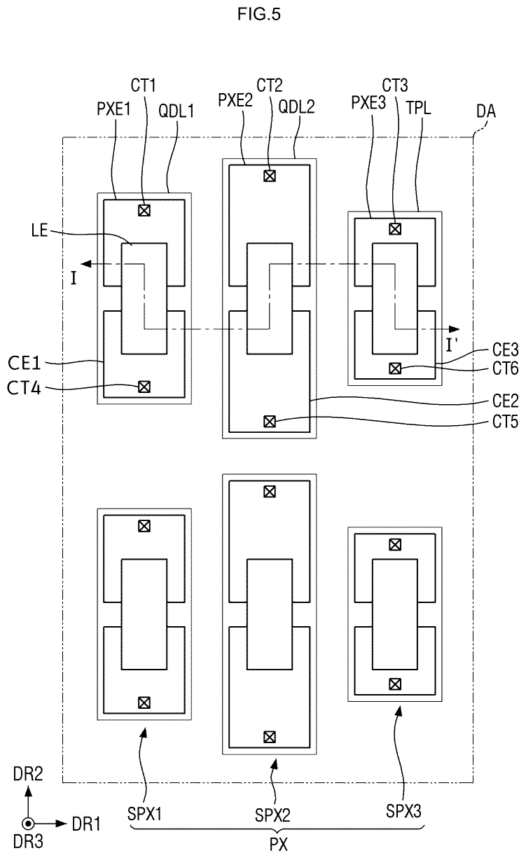

FIG. 5 is a layout diagram illustrating pixels of a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels SPX1, SPX2, and SPX3, the first sub-pixel SPX1, the second sub-pixel SPX2, and the third sub-pixel SPX3 may include.

The plurality of pixels PX may be arranged in a matrix form. In each of the plurality of pixels PX, the first sub-pixel SPX1, the second sub-pixel SPX2, and the third sub-pixel SPX3 may be arranged along a first direction DR1.

When each of the plurality of pixels PX includes three sub-pixels SPX1, SPX2, and SPX3, the first sub-pixel SPX1 may emit light of a first color, and the second sub-pixel SPX2 may emit light of a second color, and the third sub-pixel SPX3 may emit light of a third color. Here, the first color light may be light in a red wavelength band, the second color light may be light in a green wavelength band, and the third color light may be light in a blue wavelength band. For example, the blue wavelength band may refer to light having a main peak wavelength in the wavelength band from approximately 370 nm to 460 nm, the green wavelength band may refer to light having a main peak wavelength in the wavelength band from approximately 480 nm to 560 nm, and the red wavelength band may refer to light having a main peak wavelength in the wavelength band from approximately 600 nm to 750 nm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1, a first common electrode CE1, a plurality of light emitting elements LE, and a first light conversion layer QDL1. The second sub-pixel SPX2 includes a second pixel electrode PXE2, a second common electrode CE2, the plurality of light emitting elements LE, and the second light conversion layer QDL2. The third sub-pixel SPX3 includes a third pixel electrode PXE3, a third common electrode CE3, a plurality of light emitting elements LE, and a third light conversion layer QDL3.

In each of the first sub-pixel SPX1, the second sub-pixel SPX2, and the third sub-pixel SPX3, the pixel electrodes PXE1, PXE2, and PXE3 and the common electrodes CE1, CE2, and CE3 may be arranged along the second direction DR2. Each of the pixel electrodes PXE1, PXE2, and PXE3 and the common electrodes CE1, CE2, and CE3 may have a rectangular planar shape, but the present disclosure is not limited thereto. The area of the first pixel electrode PXE1 may be the same as the area of the first common electrode CE1, the area of the second pixel electrode PXE2 may be the same as the area of the second common electrode CE2, and the area of the third pixel electrode PXE3 may be the same as the area of the third common electrode CE3, but the present disclosure is not limited thereto.

For example, as shown in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1, and the area of the second common electrode CE2 may be larger than the area of the first common electrode CE1. Also, while the light transmission layer TPL transmits light of the light emitting element LE as it is, the first light conversion layer QDL1 need to convert the light. Therefore, the area of the first pixel electrode PXE1 may be larger than the area of the third pixel electrode PXE3, and the area of the first common electrode CE1 may be larger than the area of the third common electrode CE3.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the first electrode of the fourth transistor (ST4 in FIG. 4) and the second electrode of the sixth transistor (ST6 in FIG. 4) of the corresponding sub-pixel.

The first common electrode CE1 may be connected to the second power supply line VSL to which a second driving voltage VSS is applied through a first common connection hole CT4. The second common electrode CE2 may be connected to the second power supply line VSL through a second common connection hole CT5. The third common electrode CE3 may be connected to the second power supply line VSL through a third common connection hole CT6. Therefore, the second driving voltage VSS may be applied to each of the common electrodes CE1, CE2, and CE3. The pixel electrodes PXE1, PXE2, and PXE3 may be referred to as an anode electrode or a first electrode, and the common electrode CE may be referred to as a cathode electrode or a second electrode.

The plurality of light emitting elements LE may be disposed on the pixel electrodes PXE1, PXE2, and PXE3 and the common electrodes CE1, CE2, and CE3. Each of the plurality of light emitting elements LE may have a rectangular planar shape, but the present disclosure is not limited thereto. For example, each of the plurality of light emitting elements LE may have a circular planar shape.

The first light conversion layer QDL1 may completely overlap the plurality of light emitting elements LE of the first sub-pixel SPX1. The first light conversion layer QDL1 may convert or shift the peak wavelength of incident light into light of another specific peak wavelength and emit it. For example, the first light conversion layer QDL1 may convert or shift the third light emitted from the plurality of light emitting elements LE of the first sub-pixel SPX1 into first light.

The second light conversion layer QDL2 may completely overlap the plurality of light emitting elements LE of the second sub-pixel SPX2. The area of the second light conversion layer QDL2 may be larger than the area of the second pixel electrode PXE2. The second light conversion layer QDL2 may convert or shift the peak wavelength of incident light into light of another specific peak wavelength and emit it. For example, the second light conversion layer QDL2 may convert or shift the third light emitted from the plurality of light emitting elements LE of the second sub-pixel SPX2 into second light.

The light transmission layer TPL may completely overlap the plurality of light emitting elements LE of the third sub-pixel SPX3. The light transmission layer TPL may transmit incident light as it is. For example, the light transmission layer TPL may directly transmit the third light emitted from the plurality of light emitting elements LE of the third sub-pixel SPX3.

When the light emitting element LE of the first sub-pixel SPX1 emits light of the first color, the light emitting element LE of the second sub-pixel SPX2 emits light of the second color, and the light emitting element LE of the third sub-pixel SPX3 emits light of the third color, the light conversion layers QDL1 and QDL2 and the light transmission layer TPL may be omitted.

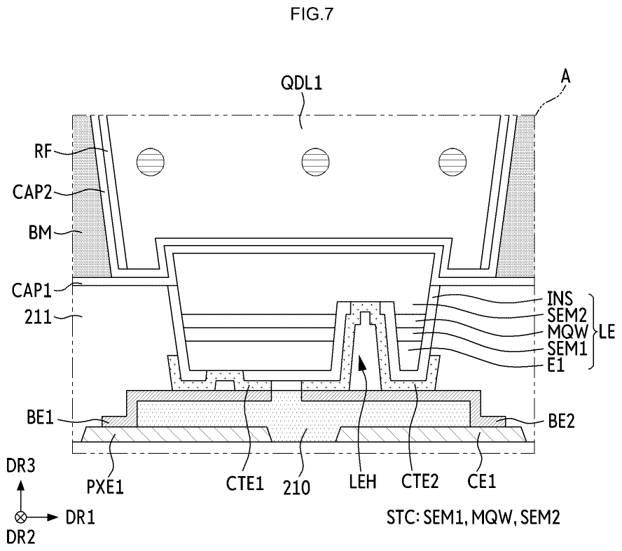

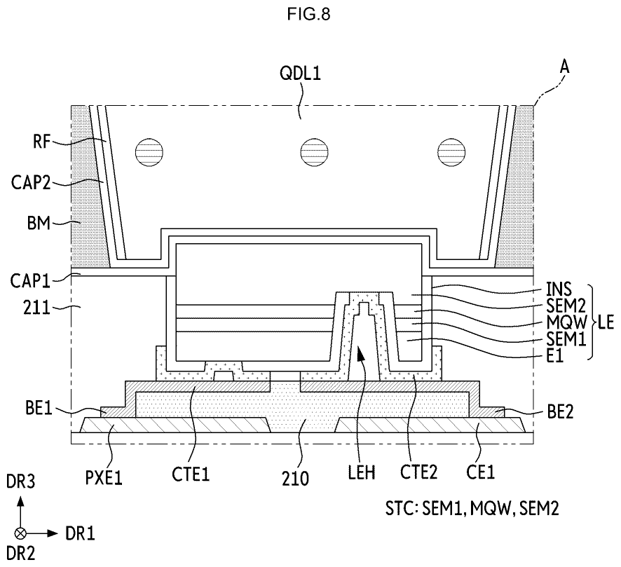

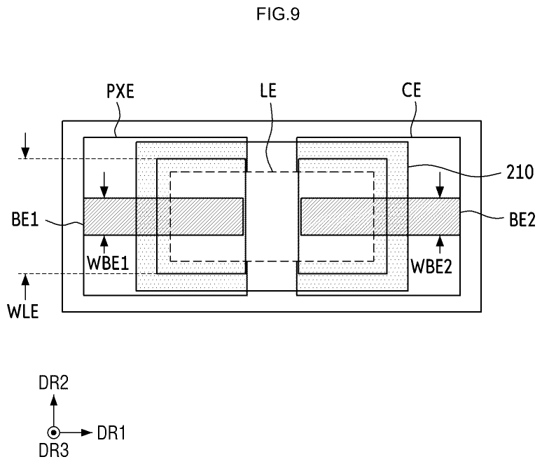

FIG. 6 is a cross-sectional view illustrating an example cross-section of one display panel corresponding to the lines I-I′ in FIG. 5. FIG. 7 is a cross-sectional view illustrating one example of an area A in FIG. 6 in detail. FIG. 8 is a cross-sectional view illustrating another example of the area A in FIG. 6 in detail. FIG. 9 is a plan view illustrating the associated structure of a light emitting element, a connection electrode, and an organic layer in a sub-pixel according to one or more embodiments.

Referring to FIGS. 6 and 7, a substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be disposed on the substrate SUB. The barrier film BR is a film that protects the transistors of the thin film transistor layer TFTL and the light emitting layer 172 of the light emitting element layer EML from moisture penetrating through the substrate SUB, which is vulnerable to moisture penetration. The barrier film BR may be composed of a plurality of inorganic films stacked alternately.

A thin film transistor TFT1 may be disposed on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be disposed on the barrier film BR. The first active layer ACT1 of the thin film transistor TFT1 may include polycrystalline silicon, monocrystalline silicon, low-temperature polycrystalline silicon, and/or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), and/or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be disposed on the first channel area CHA1, the first source area S1, and the first drain area D1 of the thin film transistor TFT1 and the barrier layer BR.

A first gate metal layer may be disposed on a first gate insulating film 131. The first gate metal layer may include the first gate electrode G1 and the first capacitor electrode CAE1 of the thin film transistor TFT1. The first gate electrode G1 may overlap the first active layer ACT1 in the third direction DR3. In FIG. 6, the first gate electrode G1 and the first capacitor electrode CAE1 are shown to be spaced (e.g., spaced apart) from each other, but the first gate electrode G1 and the first capacitor electrode CAE1 may be connected to each other.

A second gate insulating film 132 may be disposed on the first gate electrode G1 of the thin film transistor TFT1 and the first capacitor electrode CAE1, and the first gate insulating layer 131.

A second gate metal layer may be disposed on the second gate insulating film 132. The second gate metal layer may include a second capacitor electrode CAE2. The second capacitor electrode CAE2 may overlap the first capacitor electrode CAE1 of the thin film transistor TFT1 in the third direction DR3. Because the second gate insulating film 132 has a suitable dielectric constant (e.g., a predetermined dielectric constant), the capacitor (C1 in FIG. 4) may be formed by the first capacitor electrode CAE1, the second capacitor electrode CAE2, and the second gate insulating film 132 disposed between them.

A first interlayer insulating film 141 may be disposed on the second capacitor electrode CAE2 and the second gate insulating layer 132.

A first data metal layer may be disposed on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the first interlayer insulating film 141.

A first planarization organic film 160 may be disposed on the first source connection electrode PCE1 and the first interlayer insulating layer 141 to planarize a step caused by the thin film transistor TFT1.

A second data metal layer may be disposed on the first planarization organic film 160. The second data metal layer may include a second source connection electrode PCE2. The second source connection electrode PCE2 may be connected to the first source connection electrode PCE1 through a second source contact hole PCT2 penetrating the first planarization organic film 160.

A second planarization organic film 180 may be disposed on the second source connection electrode PCE2 and the first planarization layer 160.

The barrier film BR, the first gate insulating film 131, the second gate insulating film 132, the third gate insulating film 133, and the first interlayer insulating film 141 may be formed from an inorganic film, for example, silicon nitride (SiNₓ), silicon oxide (SiON), silicon oxide (SiOₓ), titanium oxide (TiOₓ), and/or aluminum oxide (AlOₓ).

The first gate metal layer, the second gate metal layer, the first data metal layer, and the second data metal layer may be formed as a single layer or multiple layers of molybdenum (Mo), aluminum (Al), chromium (Cr), gold (Au), titanium (Ti), nickel (Ni), neodymium (Nd), and copper (Cu), and/or an alloy thereof.

The first planarization organic film 160 and the second planarization organic film 180 may be formed of an organic film such as an acrylic resin, an epoxy resin, a phenolic resin, a polyamide resin, a polyimide resin, and/or the like.

A light emitting element layer may be disposed on the second planarization organic film 180. The light emitting element layer may include pixel electrodes PXE1, PXE2, PXE3, light emitting elements LE, a common electrode CE, a first organic layer 210, and a second organic film 211.

A pixel electrode layer including the pixel electrodes PXE1, PXE2, and PXE3 and the common electrodes CE1, CE2, and CE3 may be disposed on the second planarization organic film 180.

Each of the first pixel electrode PXE1, the second pixel electrode PXE2, and the third pixel electrode PXE3 may be connected to the second source connection electrode PCE2 through a connection hole (CT1, CT2, and CT3 in FIG. 5) penetrating the second planarized organic film 180. Each of the pixel electrodes PXE1, PXE2, and PXE3 may be connected to a first source area S1 or a first drain area D1 of the thin film transistor TFT1 through the first source connection electrode PCE1 and the second source connection electrode PCE2. Therefore, a voltage controlled by the thin film transistor TFT1 may be applied to each of the pixel electrodes PXE1, PXE2, and PXE3.

The common electrodes CE1, CE2, and CE3 may be connected to a second power supply line (VSL in FIG. 4) to which a second driving voltage (VSS in FIG. 3) is applied through the common connection hole (CT4, CT5, and CT6 in FIG. 5). For example, the first common electrode CE1 may be connected to the second power supply line (VSL in FIG. 4) through the first common connection hole CT4. The second common electrode CE2 may be connected to the second power supply line (VSL in FIG. 4) through the second common connection hole CT5. The third common electrode CE3 may be connected to the second power supply line VSL through the third common connection hole CT6. Therefore, the second driving voltage VSS may be applied to each of the common electrodes CE1, CE2, and CE3.

The pixel electrode layer may be formed as a single layer or multiple layers of molybdenum (Mo), aluminum (Al), chromium (Cr), gold (Au), titanium (Ti), nickel (Ni), neodymium (Nd), and/or copper (Cu), and/or alloys thereof. For example, the pixel electrode layer may be made of copper (Cu) with low sheet resistance to lower the resistance of each of the pixel electrodes PXE1, PXE2, and PXE3.

The first organic layer 210 may be disposed on each pixel electrode layer. The first organic layer 210 serves to temporarily fix or adhere the top member (e.g., the light emitting element LE). For example, the first organic layer 210 may be a film for pseudo-adhering the top member (e.g., the light emitting element LE) to each of the pixel electrodes PXE1, PXE2, and PXE3 and the common electrodes CE1, CE2, and CE3. To facilitate pseudo-adhering, the thickness of the first organic layer 210 may be greater than the thickness of each of the pixel electrodes PXE1, PXE2, and PXE3 and the common electrodes CE1, CE2, and CE3 and greater than the thickness of the contact electrode CTE (e.g., CTE1, CTE2).

The first organic layer 210 may be a photosensitive organic film, such as photoresist. Alternatively, the first organic layer 210 may be formed from an acrylic resin, an epoxy resin, a phenolic resin, a polyamide resin, a polyimide resin, and/or the like.

A plurality of light emitting elements LE may be disposed on the first organic layer 210. FIGS. 6 and 7 illustrate that the light emitting element LE is a flip-type micro LED. The flip-type micro LED refers to an LED in which contact electrodes CTE1 and CTE2 are formed on one side (e.g., the bottom side) of the light emitting element LE. The light emitting element LE may have an inverse tapered cross-sectional shape as shown in FIG. 7. For example, the light emitting element LE may have an inverted trapezoidal cross-sectional shape where the upper surface is wider than the lower surface.

The shape of the light emitting element LE may vary depending on the embodiments. For example, the light emitting element LE may include a substantially vertical side surface as shown in FIG. 8. For example, the light emitting element LE may be patterned through vertical etching and may have a rectangular or square cross-sectional shape where the width of the top surface and the width of the bottom surface are substantially the same. Each of the plurality of light emitting elements LE may be formed from an inorganic material such as gallium nitride (GaN).

Each of the plurality of light emitting elements LE may be formed by growing on a semiconductor substrate such as a silicon substrate and/or sapphire substrate. The plurality of light emitting elements LE may be transferred onto the pixel electrode layer of the display panel 100 directly from the semiconductor substrate or through a relay substrate. Alternatively, the plurality of light emitting elements LE may be transferred onto the pixel electrodes PXE1, PXE2, and PXE3 of the display panel 100 through an electrostatic method using an electrostatic head or a stamp method using an elastic polymeric material such as PDMS or silicon as a transfer substrate.

As shown in FIGS. 7-9, the light emitting element LE may include a conductive layer E1, a semiconductor stack STC, a first contact electrode CTE1, a second contact electrode CTE2, and a protective film INS. The semiconductor stack STC may include a first semiconductor layer SEM1, an active layer MQW, and a second semiconductor layer SEM2 sequentially arranged along the third direction DR3.

The conductive layer E1 may be disposed on the lower surface of the first semiconductor layer SEM1. Although FIG. 7 illustrates that the conductive layer E1 covers the entire lower surface of the first semiconductor layer SEM1, the present disclosure is not limited thereto. In one example, the conductive layer E1 may be disposed on a portion of the lower surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

The first semiconductor layer SEM1 may be disposed on the conductive layer E1. The first semiconductor layer SEM1 may include a semiconductor material layer doped with a first conductive dopant, such as magnesium (Mg), zinc (Zn), calcium (Ca), strontium (Sr), barium (Ba), and/or the like, for example gallium nitride (GaN).

In one or more embodiments, the first semiconductor layer SEM1 may have a multilayer structure. For example, the first semiconductor layer SEM1 may include a P−GaN layer and a P+GaN layer. The P+GaN layer may be disposed below the P−GaN layer. The P+GaN layer may be a layer overdoped with a first conductivity type dopant. The P+GaN layer may be formed to a thickness of several nanometers or tens of degrees on the top to aid ohmic formation. P+GaN is very useful in lowering the operating voltage by improving the ohmic characteristics with the top metal through the tunneling effect.

The active layer MQW may be disposed on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) and/or aluminum gallium nitride (AlGaN), but the present disclosure is not limited thereto.

Alternatively, the active layer MQW may have a structure in which semiconductor materials having a high band gap energy and semiconductor materials having a low band gap energy are alternately stacked with each other, may include other Group III to V semiconductor materials according to the wavelength range of emitted light.

For example, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (light in the blue wavelength band) may be approximately 10 wt % to 20 wt %.

The second semiconductor layer SEM2 may be disposed on the active layer MQW. The second semiconductor layer SEM2 may be a semiconductor material layer doped with a second conductivity type dopant such as silicon (Si), germanium (Ge), tin (Sn), etc., for example, gallium nitride (GaN).

In one or more embodiments, the second semiconductor layer SEM2 may have a multilayer structure. For example, the second semiconductor layer SEM2 may include an N−GaN layer and an N+GaN layer disposed on the N−GaN layer. The N+GaN layer may be a layer overdoped with a second conductivity type dopant. The N+GaN layer may increase the overall uniform luminescence of the light emitting element LE by lowering electrical resistance and improving current distribution when forming an ohmic electrode.

An electron blocking layer may be disposed between the first semiconductor layer SEM1 and the active layer MQW. The electron blocking layer may be a layer to suppress or prevent too many electrons from flowing into the active layer MQW. For example, the electron blocking layer may be aluminum gallium nitride (AlGaN) or p-type aluminum gallium nitride (AlGaN) doped with p-type magnesium (Mg). The electronic blocking layer may be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

The protective film INS may be a film to protect the bottom and side surfaces (e.g., outer peripheral surfaces) of the light emitting element LE. The protective film INS may be disposed on the bottom and side surfaces of the conductive layer E1 and on the side surfaces of the semiconductor stack STC. Specifically, the protective film INS may be disposed on the bottom and side surfaces of the conductive layer E1, on the side surface of the first semiconductor layer SEM1, on the side surface of the active layer MQW, and on the side surface of the second semiconductor layer SEM2.

The protective film INS may be formed of an inorganic film, for example, silicon nitride (SiNₓ), silicon oxide (SiON), silicon oxide (SiOₓ), titanium oxide (TiOₓ), and/or aluminum oxide (AlOₓ).

As described above, the plurality of light emitting elements LE are grown on a semiconductor substrate and transferred to the display panel 100 by a process, the protective film INS of an area adjacent to one side of the semiconductor stack STC where the semiconductor substrate and the semiconductor stack STC are in contact may be partially removed. As a result, the area adjacent to the top surface of the semiconductor stack STC from among the side surfaces of the semiconductor stack STC may be exposed by the protective film INS. For example, the protective film INS may be spaced (e.g., spaced apart) from the top surface of the semiconductor stack STC in the third direction DR3. Here, the third direction DR3 may be substantially the same as the height direction (or thickness direction (e.g., the third direction DR3)) of the light emitting element LE.

A hole LEH exposing the second semiconductor layer SEM2 may be formed through the conductive layer E1, the first semiconductor layer SEM1, and the active layer MQW of the light emitting element LE. The hole LEH may have a rectangular plan shape, but the present disclosure is not limited thereto. For example, the hole LEH may have a polygonal plan shape such as a circle, an oval, and/or a square.

In addition, the protective film INS may be disposed on the sidewall of the conductive layer E1 exposed in the hole LEH, the sidewall of the first semiconductor layer SEM1, and the sidewall of the active layer MQW. The protective film INS may not cover the second semiconductor layer SEM2 in the hole LEH. Therefore, the second semiconductor layer SEM2 may be exposed without being covered by the protective film INS.

The first contact electrode CTE1 may be disposed on at least one side of the semiconductor stack STC and on at least one side and bottom of the conductive layer E1. The first contact electrode CTE1 may be disposed on the exposed bottom surface of the conductive layer E1 that is not covered by the protective film INS. Therefore, the first contact electrode CTE1 may be electrically connected to the conductive layer E1.

The second contact electrode CTE2 may be disposed on at least one side of the semiconductor stack STC and on at least one side and bottom of the conductive layer E1. In this case, the first contact electrode CTE1 may be disposed on the first side of the semiconductor stack STC and the first side of the conductive layer E1, while the second contact electrode CTE2 may be disposed on the first side of the semiconductor stack STC and the second side of the conductive layer E1.

The second contact electrode CTE2 may be disposed on the protective film INS disposed in the hole LEH and the second semiconductor layer SEM2 exposed in the hole LEH without being covered by the protective film INS. Therefore, the second contact electrode CTE2 may be electrically connected to the second semiconductor layer SEM2 in the hole LEH.

The first contact electrode CTE1 and the second contact electrode CTE2 may be disposed on at least a portion of the side surface of the semiconductor stack STC. From among the side surfaces of the semiconductor stack STC, at least an area adjacent to the top surface of the semiconductor stack STC may be exposed without being covered by the first and second contact electrodes CTE1 and CTE2. For example, the first and second contact electrodes CTE1 and CTE2 may be spaced (e.g., spaced apart) from the top surface of the semiconductor stack STC in the third direction DR3.

In addition, a separation distance between the top surface of the semiconductor stack STC and the contact electrodes CTE1 and CTE2 in the third direction DR3 may be larger than the separation distance between the top surface of the semiconductor stack STC and the protective film INS in the third direction DR3. Accordingly, it is possible to reduce or minimize or prevent the possibility that a leakage current may be formed in an abnormal path inside the top surface of the light emitting element LE, causing a decrease in luminance, dark spots, bright spots, etc., of the light emitting element.

The first contact electrode CTE1 and the second contact electrode CTE2 may include molybdenum (Mo), aluminum (Al), chromium (Cr), gold (Au), titanium (Ti), nickel (Ni), neodymium (Nd), and/or copper (Cu). Specifically, the first contact electrode CTE1 and the second contact electrode CTE2 may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The first connection electrode BE1 may be disposed between the first contact electrode CTE1 and the first organic layer 210 and may extend along the first organic layer 210 onto the pixel electrodes PXE1, PXE2, and PXE3. The first connection electrode BE1 connects the first contact electrode CTE1 of the light emitting element LE and the pixel electrodes PXE1, PXE2, and PXE3.

The second connection electrode BE2 may be disposed between the second contact electrode CTE2 and the first organic layer 210 and may extend along the first organic layer 210 onto the common electrodes CE1, CE2, and CE3. The second connection electrode BE2 connects the second contact electrode CTE2 of the light emitting element LE and the common electrodes CE1, CE2, and CE3.

By disposing the first connection electrode BE1 and the second connection electrode BE2 between the first contact electrode CTE1 and the second contact electrode CTE2 and the first organic layer 210, rather than extending to the side of the light emitting element LE, cracking may be reduced or minimized or prevented at the boundary where the light emitting element LE and the connection electrodes BE1 and BE2 are in contact.

In a plan view, the first connection electrode BE1 and the second connection electrode BE2 expose at least a portion of the first organic layer 210 on the surface where the light emitting element LE and the first organic layer 210 overlap. As used herein, “in a plane” or “in a plan view” is set relative to a plane parallel to the plane defined by the first direction DR1 and the second direction DR2. For example, referring to FIG. 9, the width WBE1 of the first connection electrode BE1 and the width WBE2 of the second connection electrode BE2 may be narrower than the width WLE of the light emitting element LE.

In one or more embodiments, when the first organic layer 210 is made of a photosensitive organic material such as photoresist, after soft baking the first organic layer 210 at the first temperature, and the light emitting element LE is disposed on the first organic layer 210 after forming the first connection electrode BE1 and the second connection electrode BE2. Due to the pressure when the light emitting element LE is placed on the first organic layer 210, the first organic layer 210 in the soft cured state is convexly formed such that the portion (or exposed portion) where the first connection electrode BE1 and the second connection electrode BE2 are not placed is higher than the portion where the first connection electrode BE1 and the second connection electrode BE2 are placed, and is in contact with the light emitting element LE. Thereafter, when the first organic layer 210 is completely cured at a second temperature higher than the first temperature, the light emitting element LE may be attached to the first organic layer 210. The first temperature may be approximately 100 degrees Celsius, and the second temperature may be approximately 230 degrees Celsius, but the present disclosure are not limited thereto. Furthermore, the process of completely curing the first organic layer 210 at the second temperature may be performed for approximately 30 minutes.

On the other hand, if the first connection electrode BE1 and the second connection electrode BE2 are arranged to have a larger area than the light emitting element LE in the area overlapping the first organic layer 210 and the light emitting element LE, the first organic layer 210 and the light emitting element LE will not be able to contact, and thus the first organic layer 210 will not be able to fix the light emitting element LE. Therefore, in one or more embodiments, the first connection electrode BE1 and the second connection electrode BE2 expose at least a portion of the first organic layer 210 in the area overlapping the first organic layer 210 and the light emitting element LE, so that the light emitting element LE may be fixed by the first organic layer 210.

In one or more embodiments, the first organic layer 210 may be filled between the first connection electrode BE1 and the second connection electrode BE2 in a plane (e.g., in a plan view).

The first organic layer 210 in which the first connection electrode BE1 and the second connection electrode BE2 are not disposed may protrude upward as much as the height of the first connection electrode BE1 and the second connection electrode BE2.

Each of the first connection electrode BE1 and the second connection electrode BE2 may include molybdenum (Mo), aluminum (Al), chromium (Cr), gold (Au), titanium (Ti), nickel (Ni), neodymium (Nd), and/or copper (Cu). Specifically, each of the first connection electrode BE1 and the second connection electrode BE2 may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The second organic film 211 may be disposed to cover the side surfaces of the plurality of light emitting elements LE, the first organic layer 210, and the connection electrodes BE1 and BE2. For example, the first organic layer 210 and the connection electrodes BE1 and BE2 may be covered by the second organic layer 211. The top surface of each of the plurality of light emitting elements LE may be exposed without being covered by the second organic film 211. In other example, the second organic film 211 may include a plurality of stacked organic films. The second organic film 211 is a layer for flattening the steps caused by the plurality of light emitting elements LE.

The second organic film 211 may be formed from an organic film, such as an acrylic resin, an epoxy resin, a phenolic resin, a polyamide resin, a polyimide resin, or the like.

A first capping layer CAP1 may be disposed on the plurality of light emitting elements LE and the second organic film 211.

A light blocking layer BM, a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be separated by the light blocking layer BM. Therefore, the first light conversion layer QDL1 may be disposed on the first capping layer CAP1 in the first sub-pixel SPX1, the second light conversion layer QDL2 may be disposed on the first capping layer CAP1 in the second sub-pixel SPX2, and the light transmission layer TPL may be disposed on the first capping layer CAP1 in the third sub-pixel SPX3. The light blocking layer BM may not overlap the plurality of light emitting elements LE in the third direction DR3.

The first light conversion layer QDL1 may convert a portion of the third light (e.g., light in the blue wavelength band) incident from the light emitting element LE into first light (e.g., light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (e.g., light in the blue wavelength band) incident from the light emitting element LE into first light (e.g., light in the red wavelength band).

The second light conversion layer QDL2 may convert a portion of the third light (e.g., light in the blue wavelength band) incident from the light emitting element LE into second light (e.g., light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (e.g., light in the blue wavelength band) incident from the light emitting element LE into second light (e.g., light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cado-based resin, and/or an imide-based resin. The first and second wavelength conversion particles WCP1 and WCP2 may be quantum dots (QD), quantum rods, fluorescent materials, and/or phosphorescent materials.

The light blocking layer BM may include a first light blocking layer BM1 and a second light blocking layer BM2 that are sequentially stacked. A length of the first light blocking layer BM1 in the first direction DR1 or a length in the second direction DR2 may be wider than a length of the second light blocking layer BM2 in the first direction DR1 or a length in the second direction DR2 of the second light-receiving layer BM2. The first light blocking layer BM1 and the second light blocking layer BM2 may be formed of an organic film such as an acrylic resin, an epoxy resin, a phenolic resin, a polyamide resin, a polyimide resin, and/or the like. The first light blocking layer BM1 and the second light blocking layer BM2 may include a light blocking material to prevent light from the light emitting element LE of one sub-pixel from proceeding to the neighboring sub-pixel. For example, the first light blocking layer BM1 and the second light blocking layer BM2 may include an inorganic black pigment such as carbon black and/or an organic black pigment.

The second capping layer CAP2 may be disposed on the first capping layer CAP1 and the light blocking layer BM. The second capping layer CAP2 may be disposed on the side and top surfaces of the light blocking layer BM. That is, the second capping layer CAP2 may be disposed on the side of the first light blocking layer BM1 and the side and top surfaces of the second light blocking layer BM2.

The reflective film RF may be disposed on the second capping layer CAP2 between the light blocking layer BM and the first light conversion layer QDL1, between the light blocking layer BM and the second light conversion layer QDL2, and between the light blocking layer BM and the light transmission layer TPL. The reflective film RF may be disposed on a second capture layer CAP2 disposed on the side of the first light blocking layer BM1 and the side of the second light blocking layer BM2. The reflective film RF serves to reflect light traveling in the lateral direction from the first light conversion layer QDL1, the second light conversion layer QDL2, and the light transmission layer TPL.

The reflective film RF may include a highly reflective metal material such as aluminum (Al). The thickness of the reflective film RF may be approximately 0.1 μm.

Alternatively, the reflective film RF may include a first layer and a second layer of M (M is an integer of 2 or more) pairs having different refractive indices to serve as Distributed Bragg Reflectors (DBR). In this case, M first layers and M second layers may be arranged alternately. The first layer and the second layer may be formed of an inorganic film, for example, silicon nitride (SiNₓ), silicon oxide (SiON), silicon oxide (SiOₓ), titanium oxide (TiOₓ), and/or aluminum oxide (AlOₓ).

The third capping layer CAP3 may be disposed on the second capping layer CAP2, the first light conversion layer QDL1, the second light conversion layer QDL2, and the light transmission layer TPL.

The first capping layer CAP1, the second capping layer CAP2, and the third capping layer CAP3 may be formed of an inorganic film, for example, silicon nitride (SiNₓ), silicon oxide (SiON), silicon oxide (SiOₓ), titanium oxide (TiOₓ), and/or aluminum oxide (AlOₓ). The first light conversion layer QDL1, the second light conversion layer QDL2, and the light transmission layer TPL may be encapsulated by the first capture layer CAP1, the second capping layer CAP2, and the third capping layer CAP3.

A fourth organic film 213 may be disposed on the second capping layer CAP2. A plurality of color filters CF1, CF2, and CF3 may be disposed on the fourth organic film 213. The plurality of color filters CF1, CF2, and CF3 may include first color filters CF1, second color filters CF2, and third color filters CF3.

The first color filter CF1 disposed in the first sub-pixel SPX1 may transmit the first light (e.g., light in the red wavelength band) and absorb or block the third light (e.g., light in the blue wavelength band). Therefore, the first color filter CF1 may transmit the first light (e.g., light in the red wavelength band) that has been converted by the first light conversion layer QDL1 from among the third light (e.g., light in the blue wavelength band) emitted from the light emitting element LE and absorb or block the third light (e.g., light in the blue wavelength band) that has not been converted by the first light conversion layer QDL1. Accordingly, the first sub-pixel SPX1 may emit the first light (e.g., light in the red wavelength band).

The second color filter CF2 disposed in the second sub-pixel SPX2 may transmit the second light (e.g., light in the green wavelength band) and absorb or block the third light (e.g., light in the blue wavelength band). Therefore, the second color filter CF2 may transmit the second light (e.g., light in the green wavelength band) that has been converted by the first light conversion layer QDL1 from among the third light (e.g., light in the blue wavelength band) emitted from the light emitting element LE and absorb or block the third light (e.g., light in the blue wavelength band) that has not been converted by the first light conversion layer QDL1. Accordingly, the second sub-pixel SPX2 may emit the second light (e.g., light in the green wavelength band).

The third color filter CF3 disposed in the third sub-pixel SPX3 may transmit the third light (e.g., light in the blue wavelength band). Therefore, the third color filter CF3 may transmit the third light (e.g., light in the blue wavelength band) emitted from the light emitting element LE passing through the light transmission layer TPL. Accordingly, the third sub-pixel SPX3 may emit the third light (e.g., light in the blue wavelength band).

The first color filter CF1, the second color filter CF2, and the third color filter CF3 overlapping in the third direction DR3 may overlap with the light blocking layer BM in the third direction DR3.

A fifth organic film 214 may be disposed on the plurality of color filters CF1, CF2, and CF3 for planarization.

The fourth organic film 213 and the fifth organic film 214 may be formed from an acrylic resin, an epoxy resin, a phenolic resin, a polyamide resin, a polyimide resin, and/or the like.

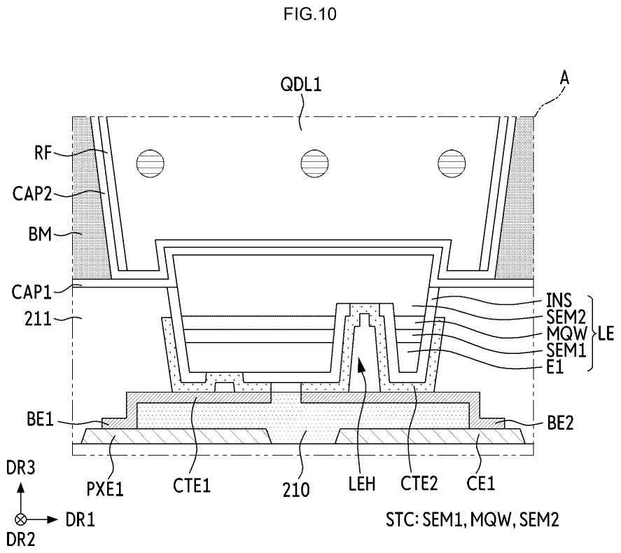

FIGS. 10-12 are cross-sectional views illustrating another example of the area A in FIG. 6 in detail.

The embodiment of FIGS. 10-12 differs from the embodiment of FIG. 7 in the length of the contact electrodes CTE1 and CTE2. In FIGS. 10-12, the embodiments described with reference to FIGS. 6 and 7 will not be described in duplicate but will be described in terms of their differences from the embodiment of FIG. 7.

Referring to FIGS. 10-12, the first contact electrode CTE1 may be disposed on at least one side of the semiconductor stack STC and on at least one side and bottom of the conductive layer E1. The first contact electrode CTE1 may be disposed on the exposed bottom surface of the conductive layer E1 that is not covered by the protective film INS. Therefore, the first contact electrode CTE1 may be electrically connected to the conductive layer E1.

The second contact electrode CTE2 may be disposed on at least one side of the semiconductor stack STC and on at least one side and bottom of the conductive layer E1. In this case, the first contact electrode CTE1 may be disposed on a first side of the semiconductor stack STC and a first side of the conductive layer E1, while the second contact electrode CTE2 may be disposed on a second side of the semiconductor stack STC and a second side of the conductive layer E1.

The second contact electrode CTE2 may be disposed on the protective film INS disposed in the hole LEH and on the second semiconductor layer SEM2 exposed in the hole LEH without being covered by the protective film INS. Therefore, the second contact electrode CTE2 may be electrically connected to the second semiconductor layer SEM2 at the hole LEH.

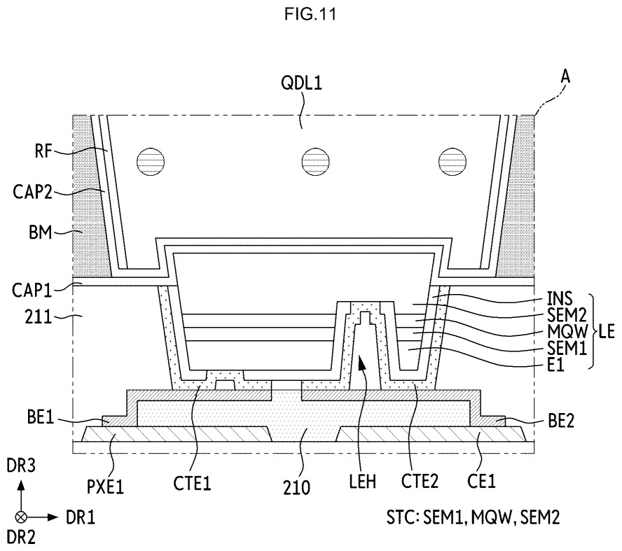

Referring to FIGS. 10 and 11, the first contact electrode CTE1 and the second contact electrode CTE2 may be disposed on at least a portion of the side surface of the semiconductor stack STC. From among the side surfaces of the semiconductor stack STC, at least an area adjacent to the top surface of the semiconductor stack STC may be exposed without being covered by the first contact electrode CTE1 and the second contact electrode CTE2. For example, the first and second contact electrodes CTE1 and CTE2 may be spaced (e.g., spaced apart) from the top surface of the semiconductor stack STC in the third direction DR3 but may cover at least the active layer MQW (e.g., the side surface of the active layer MQW).

Referring to FIG. 10, the first contact electrode CTE1 and the second contact electrode CTE2 may cover a side of the first conductive layer E1, the first semiconductor layer SEM1, the active layer MQW, and expose a side of the second semiconductor layer SEM2 from among the sides of the semiconductor stack STC.

Alternatively, referring to FIG. 11, the first contact electrode CTE1 and the second contact electrode CTE2 may cover a side of the first conductive layer E1, the first semiconductor layer SEM1, the active layer MQW, a portion of a side of the second semiconductor layer SEM2, and expose at least a portion of a side of the second semiconductor layer SEM2 from among the sides of the semiconductor stack STC.

In the embodiments of FIGS. 10 and 11, when the first contact electrode CTE1 and the second contact electrode CTE2 are made of a highly reflective metal material, the light proceeding in the downward direction of the light emitting element LE and the light proceeding to the side of the light emitting element LE (e.g., the side of the first conductive layer E1, the first semiconductor layer SEM1, and the active layer MQW) may be reflected from the first contact electrode CTE1 and the second contact electrode CTE2 and proceed in the upward direction of the light emitting element LE from among the light emitted from the active layer MQW of the light emitting element LE. Therefore, because the light loss from the light emitting element LE may be reduced, the light efficiency of the light emitting element LE may be increased.

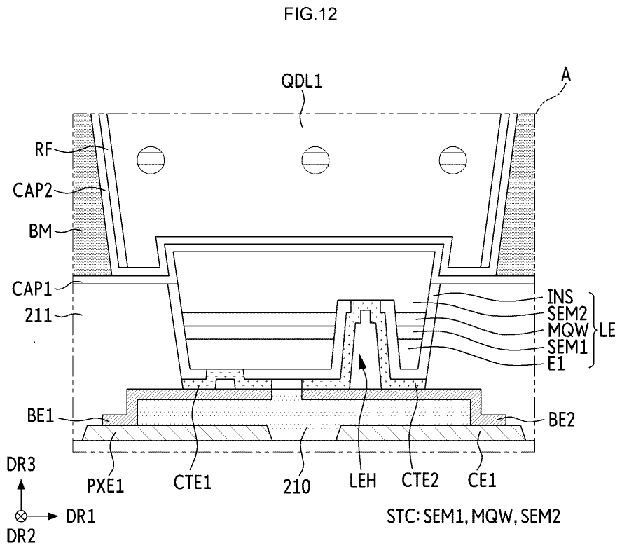

On the other hand, referring to FIG. 12, the first contact electrode CTE1 and the second contact electrode CTE2 may be disposed only on one side of the semiconductor stack STC and may not cover the side surface of the semiconductor stack STC. In this case, a separate reflective layer may be disposed to cover the side of the semiconductor stack STC.

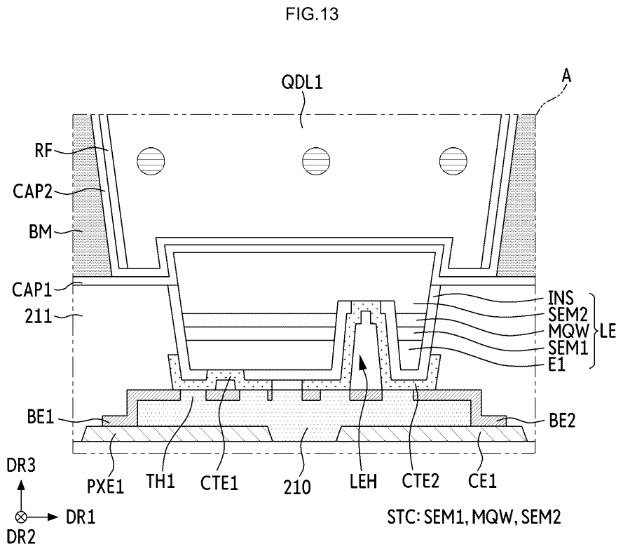

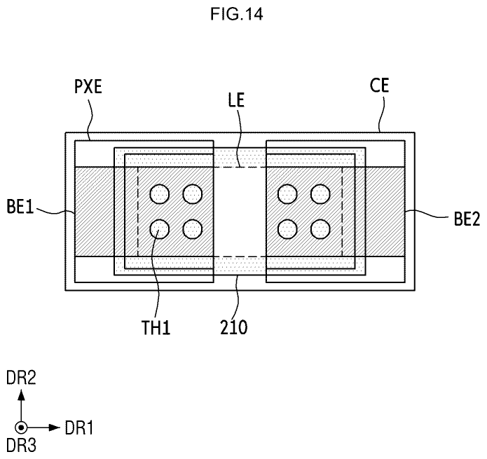

FIG. 13 is a detailed cross-sectional view illustrating another example of the area A of FIG. 6. FIG. 14 is a plan view illustrating the associated structure of the light emitting element, the connection electrode, and the organic layer in the sub-pixel corresponding to FIG. 13.

The embodiments of FIGS. 13 and 14 are different from the embodiments of FIGS. 7 and 9 in that the connection electrodes BE1 and BE2 have a plurality of through-holes TH1. In the embodiments shown in FIGS. 13 and 14, descriptions that overlap with the embodiments described with reference to FIGS. 6 and 7 will not be repeated, and the description will focus on differences from the embodiments shown in FIGS. 7 and 9.

Referring to FIGS. 13 and 14, the first connection electrode BE1 and the second connection electrode BE2 have a plurality of through-holes TH1 that penetrate the first connection electrode BE1 and the second connection electrode BE2 in an overlapping area in the thickness direction (e.g., the third direction DR3) of the first organic layer 210.

The plurality of through-holes TH1 may be filled with the first organic layer 210. The first organic layer 210 and the light emitting element LE may be in direct contact through the plurality of through-holes TH1.

As shown in FIG. 14, the through-hole TH1 may be formed in a circular shape in a plane (e.g., in a plan view), but the plane shape is not limited to a square, but may be formed in a polygonal, elliptical shape, such as another square.

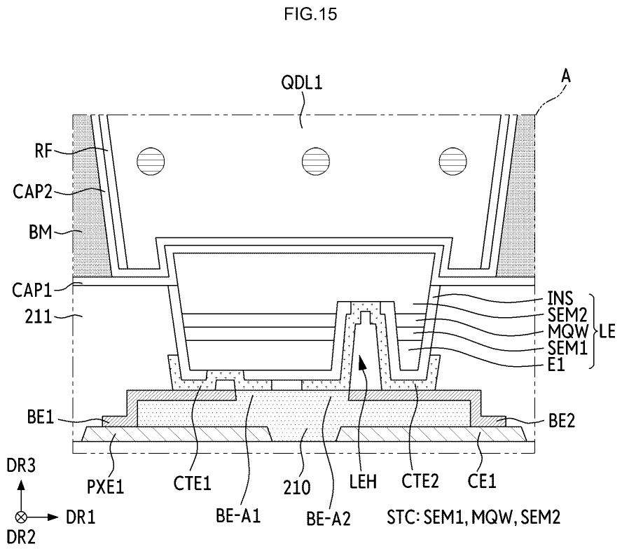

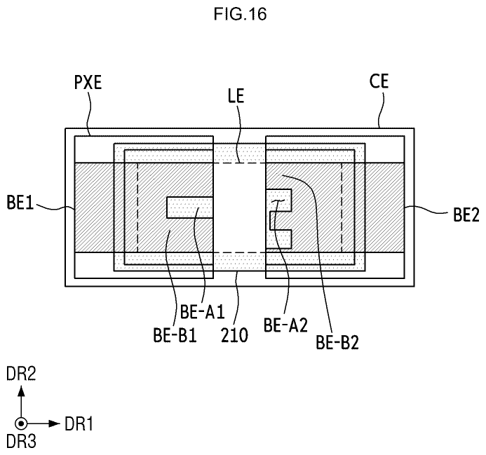

FIG. 15 is a detailed cross-sectional view illustrating another example of the area A of FIG. 6. FIG. 16 is a plan view illustrating the associated structure of light emitting element, connection electrode, and organic layer in the sub-pixel corresponding to FIG. 15.

The embodiments of FIGS. 15 and 16 are different from the embodiments of FIGS. 7 and 9 in that the connection electrodes BE1 and BE2 have a plurality of through-holes TH1. In the embodiments shown in FIGS. 15 and 16, descriptions that overlap with the embodiments described with reference to FIGS. 6 and 7 will not be repeated, and the description will focus on differences from the embodiments shown in FIGS. 7 and 9.

Referring to FIGS. 15 and 16, the first connection electrode BE1 and the second connection electrode BE2 may include concave portions BE-A1 and BE-A2 and convex portions BE-B1 and BE-B2 on the first organic layer 210. The first connection electrode BE1 and the second connection electrode BE2 may include concave portions BE-A1 and BE-A2 and convex portions BE-B1 and BE-B2 on surfaces facing each other. The concave portion BE-A1 and the convex portion BE-B1 of the first connection electrode BE1 may face the concave portion BE-A2 and the convex portion BE-B2 of the second connection electrode BE2. In FIG. 16, the concave portion BE-A1 and the convex portion BE-B1 of the first connection electrode BE1 are formed asymmetrically with respect to the concave portion BE-A2 and the convex portion BE-B2 of the second connection electrode BE2 but are not limited thereto. For example, the concave portion BE-A1 and the convex portion BE-B1 of the first connection electrode BE1 may be disposed symmetrically with respect to the concave portion BE-A2 and the convex portion BE-B2 of the second connection electrode BE2.

The concave portion BE-A1 of the first connection electrode BE1 and the concave portion BE-A2 of the second connection electrode BE2 may be filled with the first organic layer 210. The first organic layer 210 and the light emitting element LE may be in direct contact with the concave portion BE-A1 of the first connection electrode BE1 and the concave portion BE-A2 of the second connection electrode BE2.

As shown in FIG. 16, the concave portions BE-A1 and BE-A2 may be formed as rectangles in a plane (e.g., in a plan view), but the plane shape is not limited to a square, and may be formed in other polygonal, circular, and/or oval shapes.

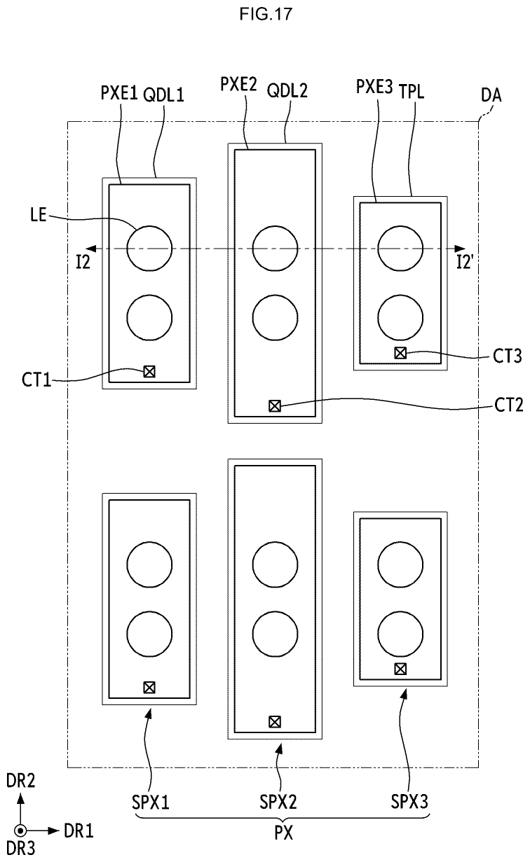

FIG. 17 is a layout diagram illustrating pixels of a display area according to one or more embodiments.

The embodiment of FIG. 17 is different from the embodiment of FIG. 5 in that the light emitting elements LE in each of the first sub-pixel SPX1, second sub-pixel SPX2, and third sub-pixel SPX3 are overlapped on the pixel electrodes PXE1, PXE2, and PXE3. In the embodiment of FIG. 17, descriptions overlapping with the embodiment of FIG. 5 will be omitted.

Referring to FIG. 17, the first sub-pixel SPX1 includes a first pixel electrode PXE1, a plurality of light emitting elements LE, and a first light conversion layer QDL1. The second sub-pixel SPX2 includes a second pixel electrode PXE2, a plurality of light emitting elements LE, and a second light conversion layer QDL2. The third sub-pixel SPX3 includes a third pixel electrode PXE3, a plurality of light emitting elements LE, and a light transmission layer (or third light conversion layer) TPL.

Each of the first pixel electrode PXE1, the second pixel electrode PXE2, and the third pixel electrode PXE3 may have a rectangular planar shape with a short side in the first direction DR1 and a long side in the second direction DR2. Depending on the light conversion efficiency of the first light conversion layer QDL1 and the light conversion efficiency of the second light conversion layer QDL2, an area of the first sub-pixel SPX1, an area of the second sub-pixel SPX2, and an area of the third sub-pixel (SPX3) may be set. For example, the lower the light conversion efficiency, the larger the area of the sub-pixel may be.

For example, as shown in FIG. 17, when the light conversion efficiency of the second light conversion layer QDL2 is lower than the light conversion efficiency of the first light conversion layer QDL1, the area of the second pixel electrode PXE2 may be larger than the area of the first subpixel electrode PXE1. In addition, the area of the first pixel electrode PXE1 may be larger than the area of the third pixel electrode PXE3 because the light transmission layer TPL transmits light from the light emitting element LE as it is, whereas the first light conversion layer QDL1 needs to convert light.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the first electrode of the fourth transistor (ST4 in FIG. 4) and the second electrode of the sixth transistor (ST6 in FIG. 4) of the corresponding sub-pixel.

The plurality of light emitting elements LE may be disposed on each of the pixel electrodes PXE1, PXE2, and PXE3. The same number of light emitting elements LE may be disposed on each of the pixel electrodes PXE1, PXE2, and PXE3. For example, two light emitting elements LE may be disposed on each of the pixel electrodes PXE1, PXE2, and PXE3.

The first light conversion layer QDL1 may completely overlap the first pixel electrode PXE1 and the plurality of light emitting elements LE of the first sub-pixel SPX1. The area of the first light conversion layer QDL1 may be larger than the area of the first pixel electrode PXE1. The first light conversion layer QDL1 may convert or shift the peak wavelength of incident light into light of another specific peak wavelength and emit it. For example, the first light conversion layer QDL1 may convert or shift the third light emitted from the plurality of light emitting elements LE of the first sub-pixel SPX1 into first light.

The second light conversion layer QDL2 may completely overlap the plurality of light emitting elements LE of the second pixel electrode PXE2 and the second sub-pixel SPX2. The area of the second light conversion layer QDL2 may be larger than the sum of the areas of the second pixel electrode PXE2 and the second common electrode CE2. The second light conversion layer QDL2 may convert or shift the peak wavelength of incident light into light of another specific peak wavelength and emit it. For example, the second light conversion layer QDL2 may convert or shift the third light emitted from the plurality of light emitting elements LE of the second sub-pixel SPX2 into second light.

The light transmission layer TPL may completely overlap the plurality of light emitting elements LE of the third pixel electrode PXE3 and the third sub-pixel SPX3. The area of the light transmission layer TPL may be larger than the sum of the areas of the third pixel electrode PXE3 and the third common electrode CE3. For example, the light transmission layer TPL may directly transmit the third light emitted from the plurality of light emitting elements LE of the third sub-pixel SPX3.

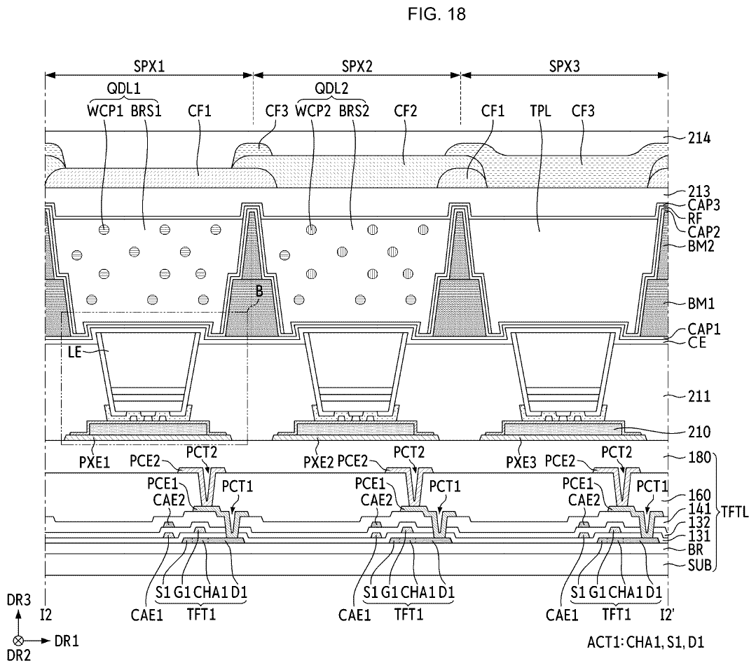

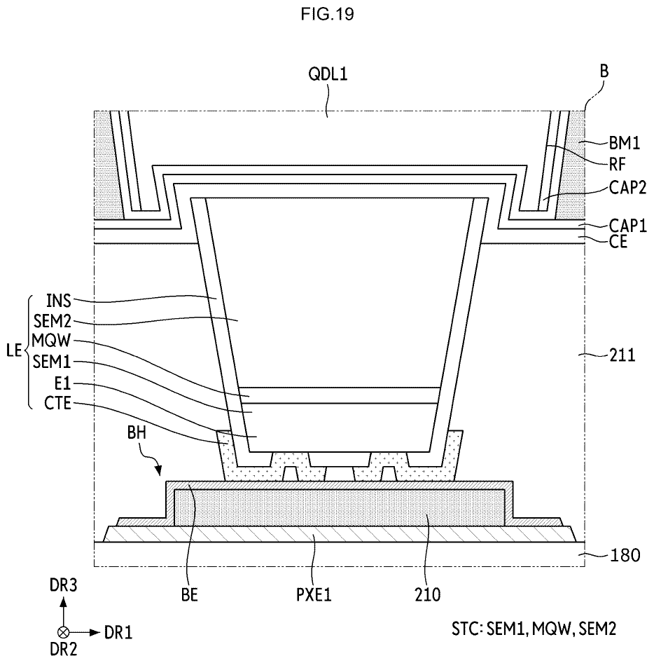

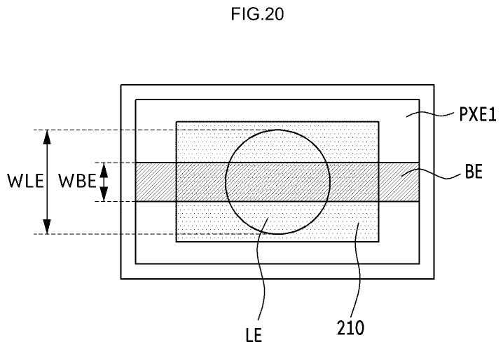

FIG. 18 is a cross-sectional view illustrating an example of a cross-section of a display panel corresponding to the line I2-I2′ of FIG. 17. FIG. 19 is a cross-sectional view illustrating an example of an area B in FIG. 18 in detail. FIG. 20 is a plan view illustrating an example of a sub-pixel according to one or more embodiments.

The embodiments of FIGS. 18 and 19 differ from the embodiments of FIGS. 6 and 7 in that the light emitting elements LE are vertical type micro LED in which each of the plurality of light emitting elements LE extends in the third direction DR3. A vertical micro LED refers to an LED having a structure in which a first semiconductor layer SEM1, an active layer MQW, and a second semiconductor layer SEM2 are sequentially arranged along the vertical third direction DR3. Each of the plurality of light emitting elements LE may have an inverse tapered cross-sectional shape. For example, each of the plurality of light emitting elements LE may have a trapezoidal cross-sectional shape where the top surface is wider than the bottom surface. The shape of the light emitting element LE may vary depending on the embodiments. For example, each of the plurality of light emitting elements LE may include a substantially vertical side surface. The light emitting element LE may be patterned through vertical etching and may have a rectangular or square cross-sectional shape where the width of the top surface and the width of the bottom surface are substantially equal.

In the embodiments of FIGS. 18 and 19, descriptions overlapping with those of the embodiments of FIGS. 6 and 7 will be omitted.

Referring to FIGS. 18 and 19, a pixel electrode layer including pixel electrodes PXE1, PXE2, and PXE3 and common electrodes CE1, CE2, and CE3 may be disposed on the second planarization organic film 180.

A pixel electrode layer may be disposed on the second planarization organic film 180. The pixel electrode layer may include a first pixel electrode PXE1, a second pixel electrode PXE2, and a third pixel electrode PXE3.

A first organic layer 210 may be disposed on each of the pixel electrodes PXE1, PXE2, and PXE3.

A plurality of light emitting elements LE may be disposed on the first organic layer 210.

Each of the plurality of light emitting elements LE may have a length of several to hundreds of μm in the first direction DR1, a length in the second direction DR2, and a length in the third direction DR3. For example, each of the plurality of light emitting elements LE may have a length in the first direction DR1, a length in the second direction DR2, and a length in the third direction DR3 of approximately 100 μm or less.

The light emitting element LE may include a conductive layer E1, a semiconductor stack STC, a contact electrode CTE, and a protective film INS. The semiconductor stack STC may include a first semiconductor layer SEM1, an active layer MQW, and a second semiconductor layer SEM2 sequentially disposed along the third direction DR3.

The protective film INS may be disposed on the side of the first semiconductor layer SEM1, the side of the active layer MQW, and the side of the second semiconductor layer SEM2. The protective film INS may be a film to protect the side surface of the light emitting element LE. The protective film INS may be formed of an inorganic film, for example, silicon nitride (SiNₓ), silicon oxide (SiON), silicon oxide (SiOₓ), titanium oxide (TiOₓ), or aluminum oxide (AlOₓ).

The contact electrode CTE may be disposed on the protective film INS. The contact electrode CTE may be disposed between the first organic layer 210 and the protective layer INS. In one or more embodiments, the contact electrode CTE may be in contact with the first organic layer 210.

The contact electrode CTE may be connected to the exposed conductive layer E1 without being covered by the protective film INS. As a result, even if one of the contact electrodes CTE is not connected to the conductive layer E1 due to a process error, the other contact electrode CTE is connected to the conductive layer E1, thereby preventing the failure of the light emitting element LE to light up.

When the contact electrode CTE is formed of a metal with high reflectivity, light emitted from the active layer MQW of the light emitting element LE may be reflected by the contact electrode CTE and emitted to the top surface of the light emitting element LE from among the light emitted from the active layer MQW of the light emitting element LE in the lateral direction of the light emitting element LE. Therefore, because light loss from the light emitting element LE may be reduced, the light efficiency of the light emitting element LE may be increased.

The contact electrode CTE may include molybdenum (Mo), aluminum (Al), chromium (Cr), gold (Au), titanium (Ti), nickel (Ni), neodymium (Nd), and/or copper (Cu). Specifically, the contact electrode CTE may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The connection electrode BE may be disposed between the contact electrode CTE and the first organic layer 210 and may extend along the first organic layer 210 onto the pixel electrodes PXE1, PXE2, and PXE3. The connection electrode BE connects the contact electrode CTE of the light emitting element LE with one of the pixel electrodes PXE1, PXE2, and PXE3.

In a plan view, as shown in FIG. 20, the connection electrode BE exposes at least a portion of the first organic layer 210. As used herein, “in a plane” (e.g., in a plan view) is set based on a plane parallel to the plane defined by the first direction DR1 and the second direction DR2. For example, referring to FIG. 20, the width WBE of the connection electrode BE may be narrower than the width WLE of the light emitting element LE.

In one or more embodiments, when the first organic layer 210 is made of a photosensitive organic material such as photoresist, the light emitting element LE is disposed on the first organic layer 210 after soft baking the first organic layer 210 at a first temperature and forming the connection electrode BE. Due to the pressure when disposing the light emitting element LE on the first organic layer 210, the first organic layer 210 in the soft baked state is convexly formed such that the portion where the connection electrode BE is not disposed is higher than the portion where the connection electrode BE is disposed and is in contact with the light emitting element LE. Thereafter, when the first organic layer 210 is completely cured at a second temperature higher than the first temperature, the light emitting element LE may be bonded to the first organic layer 210. The first temperature may be approximately 100 degrees Celsius, and the second temperature may be approximately 230 degrees Celsius, but the present disclosure is not limited thereto. Further, the process of completely curing the first organic layer 210 at the second temperature may be performed for approximately 30 minutes.

On the other hand, if the connection electrode BE is arranged to have a larger area than the light emitting element LE in the area overlapping the first organic layer 210 and the light emitting element LE, the first organic layer 210 and the light-emitting element LE will not be able to contact, and thus the first organic layer 210 will not be able to fix the light emitting element LE. Therefore, as in one or more embodiments, the connection electrode BE has a smaller area than the light emitting element LE in the area overlapping the first organic layer 210 and the light emitting element LE, so that the light emitting element LE can be fixed by the first organic layer 210.

The connection electrode BE may include molybdenum (Mo), aluminum (Al), chromium (Cr), gold (Au), titanium (Ti), nickel (Ni), neodymium (Nd), and/or copper (Cu). Specifically, the connection electrode BE may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The second organic film 211 may be disposed to cover the side surfaces of the plurality of light emitting elements LE, the first organic layer 210, and the connection electrode BE. In one example, the first organic layer 210 and the connection electrode BE may be covered by the second organic film 211. The top surface of each of the plurality of light emitting elements LE may be exposed without being covered by the second organic film 211. In other example, the second organic film 211 may include a plurality of stacked organic layers. The second organic film 211 is a layer for flattening the steps caused by the plurality of light emitting elements LE.

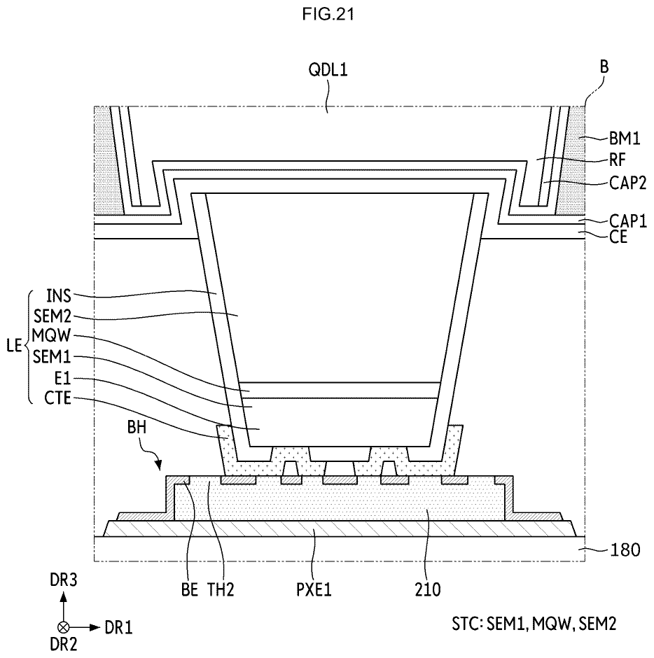

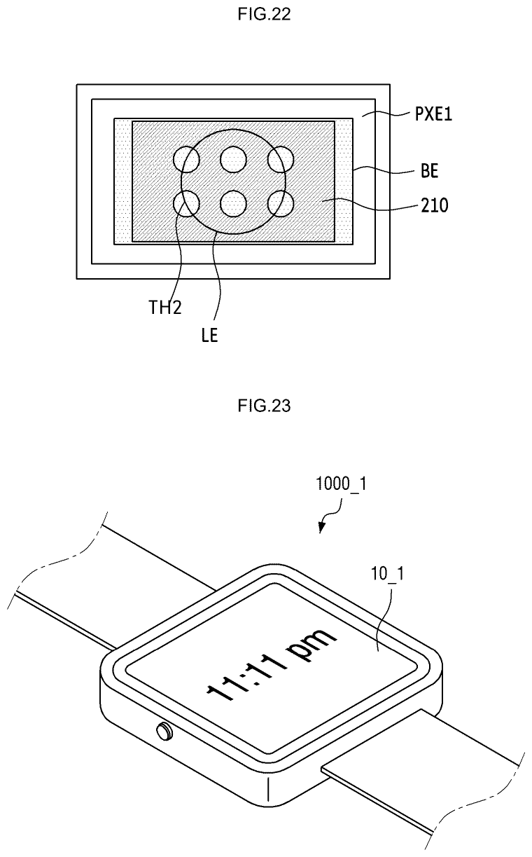

FIG. 21 is a detailed cross-sectional view illustrating another example of the area B of FIG. 18. FIG. 22 is a plan view illustrating associated structures of the light emitting elements, the connection electrodes, and the organic layers in the sub-pixel corresponding to FIG. 21.

The embodiments of FIGS. 21 and 22 are different from the embodiments of FIGS. 15 and 16 in that the connection electrode BE has a plurality of through-holes TH2. In the embodiments shown in FIGS. 21 and 22, descriptions overlapping with the embodiments described with reference to FIGS. 15 and 16 will not be repeated, and the description will focus on differences from the embodiments shown in FIGS. 15 and 16.

Referring to FIGS. 21 and 22, the connection electrode BE has a plurality of through-holes TH2 penetrating the connection electrode BE in an area overlapping the first organic layer 210 in the thickness direction (e.g., the third direction DR3).

The plurality of through-holes TH2 may be filled with the first organic layer 210. The first organic layer 210 and the light emitting element LE may be in direct contact through the plurality of through-holes TH2.

As shown in FIG. 22, the through-hole TH2 may be formed in a circular shape in the plane (e.g., in a plan view), but the plane shape is not limited to a square and may be formed in a polygonal shape such as another square, or an oval shape.

FIG. 23 is an example view of a smart watch including a display device according to one or more embodiments.

Referring to FIG. 23, a display device 10_1 according to one or more embodiments may be applied to a smart watch 1000_1 which is one of smart devices.

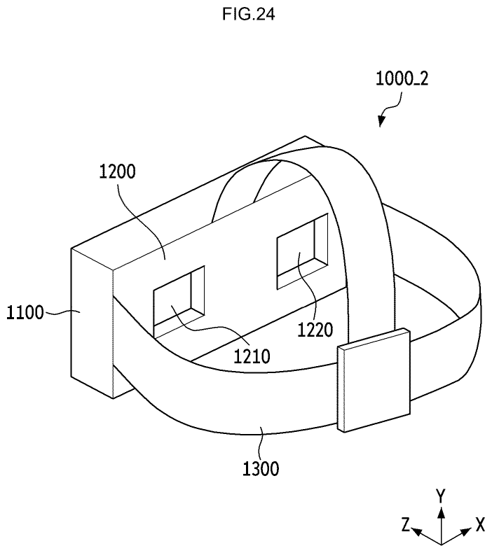

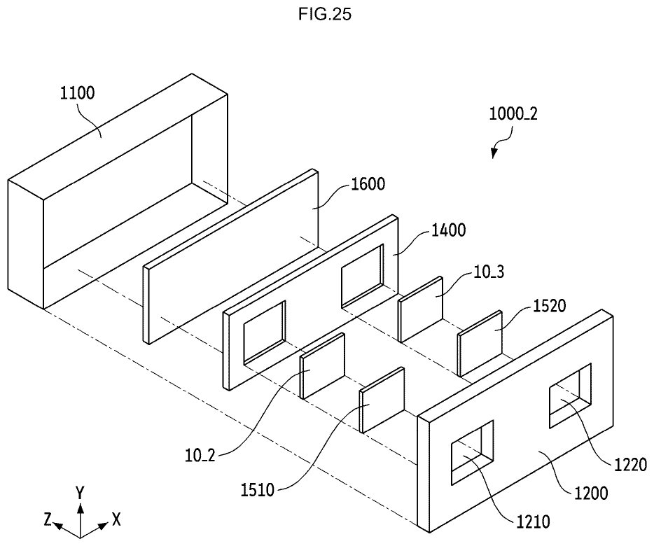

FIGS. 24 and 25 are example views of a virtual reality (VR) device including a display device according to one or more embodiments.

Referring to FIGS. 24 and 25, a head mounted display device 1000_2 according to one or more embodiments includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 10_3 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and may be disposed between the second display device 10_3 and the control circuit board 1600. The middle frame 1400 supports and fixes the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user's left eye to the first display device 10_2 and transmit the digital video data DATA corresponding to a right image optimized for the user's right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 24 and 25, the present disclosure is not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

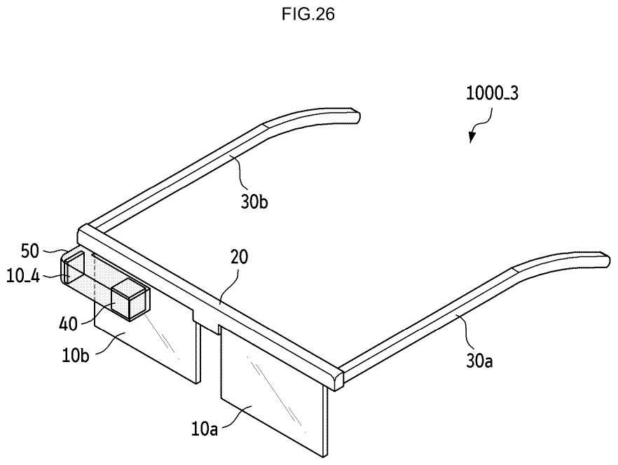

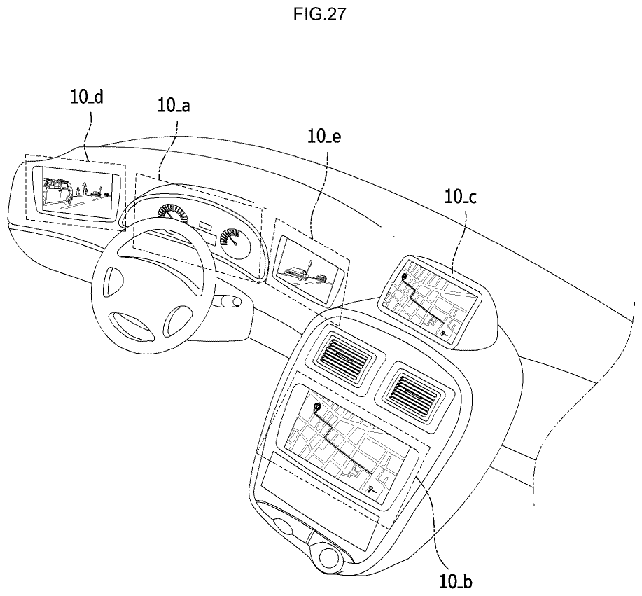

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head mounted display device 1000_2 may include an eyeglass frame as illustrated in FIG. 26 instead of the head mounted band 1300.

In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 26 is an example view of a VR device including a display device according to one or more embodiments. FIG. 26 illustrates a VR device 1000_3 to which a display device 10_4 according to one or more embodiments has been applied.

Referring to FIG. 26, the VR device 1000_3 according to one or more embodiments may be a device in the form of glasses. The VR device 1000_3 according to one or more embodiments may include the display device 10_4, a left lens 10a, a right lens 10b, a support frame 20, eyeglass frame legs 30a and 30b, a reflective member 40, and a display device housing 50.

In FIG. 26, a case where the VR device 1000_3 is a glasses-type display device including the eyeglass frame legs 30a and 30b is illustrated as an example. That is, the VR device 1000_3 according to the embodiment is not limited to the one illustrated in FIG. 26 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 26, the present disclosure is not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

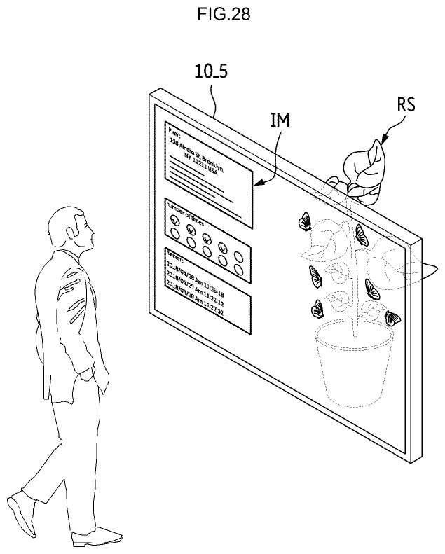

FIG. 27 is an example view illustrating a vehicle instrument cluster and center fascia including display devices according to one or more embodiments. FIG. 27 illustrates a vehicle to which display devices 10_a through 10_e according to one or more embodiments have been applied.

Referring to FIG. 27, the display devices 10_a through 10_c according to one or more embodiments may be applied to an instrument cluster of the vehicle, a center fascia of the vehicle, or a center information display (CID) disposed on a dashboard of the vehicle. In addition, the display devices 10_d and 10_e according to one or more embodiments may be applied to room mirror displays that replace side mirrors of the vehicle.

FIG. 28 is an example view of a transparent display device including a display device according to one or more embodiments.

Referring to FIG. 28, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
a substrate;
a pixel electrode and a common electrode on the substrate;
an organic layer on the pixel electrode and the common electrode;
a light emitting element on the organic layer and comprising a semiconductor stack and a first contact electrode and a second contact electrode on one surface of the semiconductor stack; and
a first connection electrode connecting the first contact electrode and the pixel electrode and a second connection electrode connecting the second contact electrode and the common electrode,
wherein the first connection electrode is between the first contact electrode and the organic layer and extends onto the pixel electrode on which the organic layer is not located,
wherein the second connection electrode is between the second contact electrode and the organic layer and extends onto the common electrode on which the organic layer is not located, and
wherein the first connection electrode and the second connection electrode expose at least a portion of the organic layer on a surface where the light emitting element and the organic layer overlap.

2. The display device of claim 1, wherein the organic layer contacts the light emitting element in an area exposed by the first connection electrode and the second connection electrode.

3. The display device of claim 1, wherein each of a width of the first connection electrode and a width of the second connection electrode is narrower than a width of the light emitting element in a plan view.

4. The display device of claim 1, wherein the first connection electrode and the second connection electrode have one or more through-holes or one or more concave portions that are concave in a plane on a surface overlapping the organic layer.

5. The display device of claim 4, wherein the organic layer contacts the light emitting element through the through-holes or the concave portions.

6. The display device of claim 4, wherein the through-hole has one of a circular shape, an oval shape, or a polygonal shape in a plane.

7. The display device of claim 1, wherein the first connection electrode and the second connection electrode are spaced from each other in a plane, and a first organic layer is filled between the first connection electrode and the second connection electrode.

8. The display device of claim 1, wherein the light emitting element further comprises:
a conductive layer between the organic layer and the semiconductor stack; and
a protective film on one side and other sides of the conductive layer and sides of the semiconductor stack,
wherein the first contact electrode is on the protective film and connected to the conductive layer exposed and not covered by the protective film, and the second contact electrode is on the protective film and is located in a hole that penetrates through the conductive layer and a portion of the semiconductor stack.

9. The display device of claim 1, wherein each of the first contact electrode and the second contact electrode is spaced from a top surface of the light emitting element.

10. The display device of claim 8, wherein the semiconductor stack comprises a first semiconductor layer, an active layer, and a second semiconductor layer arranged along a thickness direction of the light emitting element, and
wherein the first contact electrode and the second contact electrode are on an entire side surface of the conductive layer and the first semiconductor layer, on an entire side surface of the active layer, and on a portion of a side surface of the second semiconductor layer.

11. The display device of claim 8, wherein the semiconductor stack comprises a first semiconductor layer, an active layer, and a second semiconductor layer arranged along a thickness direction of the light emitting element, and
wherein the first contact electrode and the second contact electrode are on an entire side surface of the conductive layer, the first semiconductor layer, and the active layer, and expose an entire side surface of the second semiconductor layer.

12. The display device of claim 8, wherein the first contact electrode and the second contact electrode expose an entire side surface of the semiconductor stack.

13. The display device of claim 8, wherein the protective film is spaced from a top surface of the light emitting element by a first distance, and
wherein each of the first contact electrode and the second contact electrode is spaced from the top surface of the light emitting element by a second distance,
wherein the second distance is greater than the first distance.

14. The display device of claim 8, wherein the semiconductor stack further comprises:
a first semiconductor layer on the organic layer and comprising a semiconductor material layer doped with a first conductivity type dopant;
an active layer on the first semiconductor layer; and
a second semiconductor layer on the active layer and comprising a semiconductor material layer doped with a second conductivity type dopant,
wherein a hole penetrating a portion of the semiconductor stack exposes the second semiconductor layer, and
wherein the second contact electrode is in contact with the exposed second semiconductor layer.

15. A display device comprising:
a substrate;
a pixel electrode on the substrate;
an organic layer on the pixel electrode;
a light emitting element on the organic layer and comprising a semiconductor stack and a contact electrode on one surface of the semiconductor stack; and
a connection electrode between the contact electrode and the organic layer and extending onto the pixel electrode on which the organic layer is not located, and connecting the contact electrode and the pixel electrode,
wherein the connection electrode exposes at least a portion of the organic layer on a surface where the light emitting element and the organic layer overlap.

16. The display device of claim 15, wherein the organic layer is in contact with the light emitting element in an area exposed by the connection electrode.

17. The display device of claim 15, wherein a width of the connection electrode is narrower than a width of the light emitting element in a plan view.

18. The display device of claim 15, wherein the connection electrode has one or more through-holes or one or more concave portions that are concave in a plane on a surface overlapping the organic layer.

19. The display device of claim 18, wherein the organic layer is in contact with the light emitting element through the through-holes or the concave portions.

20. The display device of claim 18, wherein the through-hole has one of a circular shape, an oval shape, or a polygonal shape in a plane.

21. An electronic device comprising a display device, the display device comprising:
a substrate;
a pixel electrode and a common electrode on the substrate;
an organic layer on the pixel electrode and the common electrode;
a light emitting element on the organic layer and comprising a semiconductor stack and a first contact electrode and a second contact electrode on one surface of the semiconductor stack; and
a first connection electrode connecting the first contact electrode and the pixel electrode and a second connection electrode connecting the second contact electrode and the common electrode,
wherein the first connection electrode is between the first contact electrode and the organic layer and extends onto the pixel electrode on which the organic layer is not located,
wherein the second connection electrode is between the second contact electrode and the organic layer and extends onto the common electrode on which the organic layer is not located,
wherein the first connection electrode and the second connection electrode expose at least a portion of the organic layer on a surface where the light emitting element and the organic layer overlap, and
wherein the first connection electrode and the second connection electrode are spaced from each other in a plane, and a first organic layer is filled between the first connection electrode and the second connection electrode.

22. The electronic device of claim 21, wherein the electronic device is a mobile phone, a smartphone, a tablet personal computer (PC), a smart watch, a watch phone, a mobile communication terminal, an electronic notebook, an electronic book, a portable multimedia player (PMP), a navigation device, an ultra-mobile PC (UMPC), a television, a notebook computer, a monitor, a billboard, or an Internet of things (IoT) device.
